(19) United States
(12) Patent Application Publication
(10) Pub. No.: US 2024/0074194 A1
(43) Pub. Date: Feb. 29, 2024

(54) MEMORY DEVICE INCLUDING STAIRCASE STRUCTURES AND ADJACENT TRENCH STRUCTURES

(71) Applicant: Micron Technology, Inc., Boise, ID (US)

(72) Inventors: Shruthi Kumara Vadivel, Boise, ID (US); Harsh Narendrakumar Jain, Boise, ID (US); Richard T. Housley, Boise, ID (US); Zhenxing Han, Sunnyvale, CA (US); Scott L. Light, Boise, ID (US); Qinglin Zeng, Boise, ID (US); Hsiao-Kuan Yuan, Boise, ID (US); Jordan Chess, Boise, ID (US); Xiaosong Zhang, Boise, ID (US)

(21) Appl. No.: 18/237,661

(22) Filed: Aug. 24, 2023

Related U.S. Application Data
(60) Provisional application No. 63/401,855, filed on Aug. 29, 2022.

(51) Int. Cl. H10B 43/27; H10B 41/27

(52) U.S. Cl. CPC H10B 43/27; H10B 41/27

(57) ABSTRACT

Some embodiments include apparatuses and methods of forming the apparatuses. One of the apparatuses includes tiers located one over another; a first staircase structure formed in the tiers; a second staircase structure formed in the tiers adjacent the first staircase structure, respective portions of conductive materials in the tiers forming a part of the first and second staircase structure and a part of respective control gates associated with memory cells; a first trench structure formed in the tiers adjacent the first staircase structure and the second staircase structure, the first trench structure including length in a direction from the first staircase structure to the second staircase structure; and a second trench structure formed in the tiers adjacent the first trench structure, the second trench structure including a length in the direction from the first staircase structure to the second staircase structure.

### PRIORITY APPLICATION

This application claims the benefit of Priority to U.S. Provisional Application Ser. No. 63/401,855, filed Aug. 29, 2022, which is incorporated herein by reference in its entirety.

### FIELD

Embodiments described herein relate to memory devices including staircase regions adjacent memory cell regions and vertical conductive structures in the staircase regions.

### BACKGROUND

Some conventional memory devices have staircase structures that include vertical conductive contacts to provide electrical connections to access memory cells of the memory device. Formation of such staircase structures have many processes and often involve a use of a photoresist to form trenches for the staircase structures. Such a photoresist is prone to shrinkage during processing. The shrinkage may cause misalignment of other structures near the staircase structures and asymmetry in the staircase structures. The misalignment and asymmetry can impact or cause defects in the structure of the memory device including the staircase structures.

### BRIEF DESCRIPTION OF THE DRAWINGS

FIG. 1 shows an apparatus in the form of a memory device, according to some embodiments described herein.

FIG. 2 shows a schematic of a memory device having a memory array and memory cell blocks, according to some embodiments described herein.

FIG. 3A shows a top view of a structure of the memory device of FIG. 2 including a memory cell region, a staircase region, and dielectric structures between respective blocks of the memory device, according to some embodiments described herein.

FIG. 3B, FIG. 3C, and FIG. 3D show some detail of a portion of the memory device of FIG. 3A including staircase structure and trench structures, according to some embodiments described herein.

In FIG. 4 shows some detail of a top view of portion in FIG. 3A, including contact structures in staircase structures and memory cell pillars in memory cell region, according to some embodiments described herein.

FIG. 5 shows an enlarged portion of the memory device of FIG. 4, according to some embodiments described herein.

FIG. 6 shows detail of a portion (e.g., a side view) including a side view (in the Y-Z direction) of the staircase structures of the memory device of FIG. 4 and FIG. 5, according to some embodiments described herein.

FIG. 7 and FIG. 8 show details (e.g., side view and top view, respectively) of a conductive contact (e.g., word line contact) of the memory device of FIG. 6, according to some embodiments described herein.

FIG. 9 shows a side view of a portion including another view (in the X-Z direction) of a staircase structure of device of FIG. 3A and FIG. 4, according to some embodiments described herein.

FIG. 10 shows a top view of the portion of the memory device of FIG. 9, according to some embodiments described herein.

FIG. 11A shows a side view (e.g., cross-section) of a portion (e.g., left edge) of the memory device of FIG. 3A including a staircase structure and adjacent trench structures, according to some embodiments described herein.

FIG. 11B shows a side view (e.g., cross-section) of a portion (e.g., right edge) of the memory device of FIG. 3A including a staircase structure and adjacent trench structures, according to some embodiments described herein.

FIG. 12 shows a top view of a structure of a memory device (which can be a variation of the memory device of FIG. 3A) including additional trench structures near the edges (e.g., left and right edges) of the memory device, according to some embodiments described herein.

FIG. 13A and FIG. 13B show side views (e.g., cross-sections) of respective portions (e.g., left and right portions) of the memory device of FIG. 12, according to some embodiments described herein.

FIG. 14 shows a top view of a structure of a memory device (which can be a variation of the memory device of FIG. 3A) including variations in structures near the edges (e.g., left and right edges) of the memory device, according to some embodiments described herein.

FIG. 15A and FIG. 15B show side views (e.g., cross-sections) of respective portions (e.g., left and right portions) of the memory device of FIG. 14 including a staircase structure and adjacent trench structures, according to some embodiments described herein.

FIG. 16 shows a wafer including die portions and scribe line regions between the die portions, according to some embodiments described herein.

FIG. 17 shows a portion of the wafer of FIG. 16 including die portions, a scribe line region between the die portions, and trench structures in the scribe line region, according to some embodiments described herein.

FIG. 18 shows a memory device including a die portion of the wafer of FIG. 16 and FIG. 17 and part of scribe line regions bordering the die portion, according to some embodiments described herein.

FIG. 19A and FIG. 19B show different views of a portion of a memory device during processes of forming part of staircase structures and trench structures of the memory device, according to some embodiments described herein.

FIG. 20A and FIG. 20B show different views of a portion of another memory device during processes of forming part of staircase structures and trench structures of the memory device, according to some embodiments described herein.

FIG. 21A and FIG. 21B show different views of a portion of the wafer of FIG. 16 during processes of forming part of staircase structures and trench structures in die portions and scribe line regions of the wafer, according to some embodiments described herein.

### DETAILED DESCRIPTION

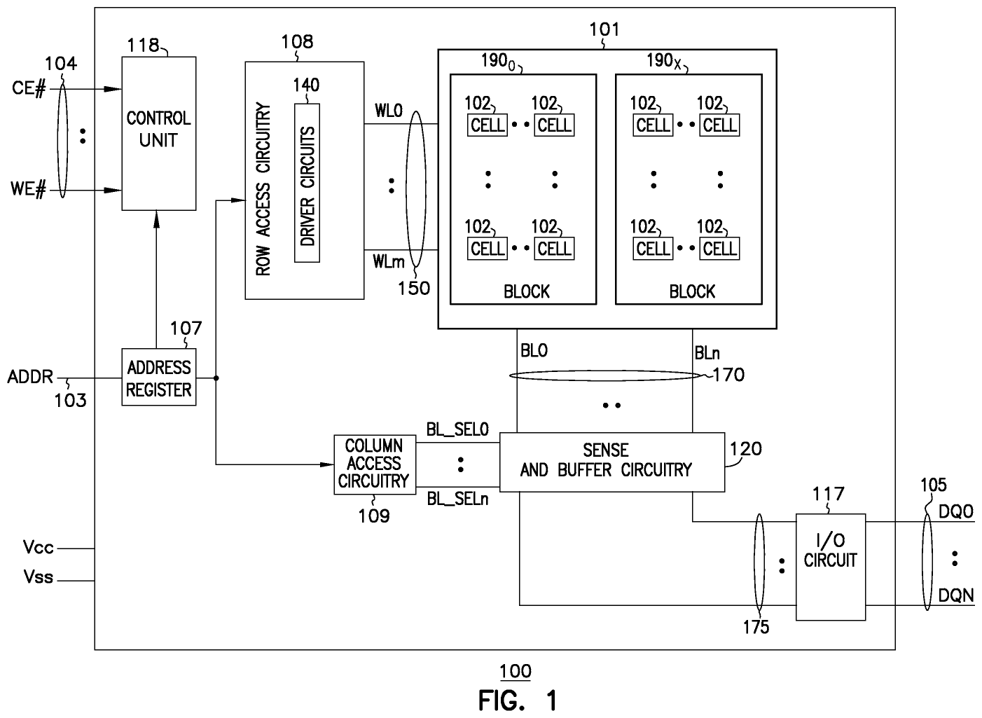

The techniques described herein involve a memory device that includes staircase structures in a staircase region and memory cells in a memory cell region. The staircase structures include conductive contacts to provide electrical connections to control gates associated with the memory cells. The described techniques also include methods of forming the described memory device. Forming the memory device having the described structures and using the described methods can reduce or eliminate potential misalignment of other structures near the staircase structures and potential asymmetry in the staircase structures. This leads to improvements in the structure of the memory device including the staircase structures. Higher yield can also be achieved. Other improvements and benefits of the described techniques are further discussed below with reference to FIG. 1 through FIG. 21B.

FIG. 1 shows an apparatus in the form of a memory device 100, according to some embodiments described herein. Memory device 100 can include a memory array (or multiple memory arrays) 101 containing memory cells 102 arranged in blocks (memory cell blocks), such as blocks 190₀ through 190_{X} (e.g., there are X+1 blocks in memory device 100). In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines 150 and data lines 170. Access lines 150 can include word lines, which can include global word lines and local word lines (e.g., control gates). Data lines 170 can include bit lines (e.g., local bit lines). Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks 190₀ through 190_{X} and data lines 170 to selectively exchange information (e.g., data) with memory cells 102.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which blocks 190₀ through 190_{X} are to be accessed during a memory operation. Memory device 100 can include drivers (driver circuits) 140, which can be part of row access circuitry 108. Drivers 140 can operate (e.g., operate as switches) to form (or not to form) conductive paths (e.g., current paths) between nodes (e.g., global access lines) providing voltages and respective access lines 150 during operations of memory device 100.

Memory device 100 can perform a read operation to read (e.g., sense) information (e.g., previously stored information) from memory cells 102 of blocks 190₀ through 190_{X}, or a write (e.g., programming) operation to store (e.g., program) information in memory cells 102 of blocks 190₀ through 190_{X}. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks 190₀ through 190_{X}.

Memory device 100 can include a control unit 118 that can be configured to control memory operations of memory device 100 based on control signals on lines 104. Examples of the control signals on lines 104 include one or more clock signals and other signals (e.g., a chip-enable signal CE #, a write-enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that may cause memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks 190₀ through 190_{X} and provide the value of the information to lines 175, which can include global data lines (e.g., global bit lines). Sense and buffer circuitry 120 can also be configured to use signals on lines 175 to determine the value of information to be stored (e.g., programmed) in memory cells 102 of blocks 190₀ and 190_{X} (e.g., during a write operation) based on the values (e.g., voltage values) of signals on lines 175 (e.g., during a write operation).

Memory device 100 can include input/output (I/O) circuitry 117 to exchange information between memory cells 102 of blocks 190₀ through 190_{X} and lines (e.g., I/O lines) 105. Signals DQ0 through DQN on lines 105 can represent information read from or stored in memory cells 102 of blocks 190₀ through 190_{X}. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages V_{CC} and V_{SS}. Supply voltage V_{SS} can operate at a ground potential (e.g., having a value of approximately zero volts). Supply voltage V_{CC} can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits. A cell that can store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage V_{CC}, V_{SS}, or both) is disconnected from memory device 100. For example, memory device 100 can be a flash memory device, such as a NAND flash (e.g., 3-dimensional (3-D) NAND) or a NOR flash memory device, or another kind of memory device, such as a variable resistance memory device (e.g., a phase change memory device or a resistive Random-Access Memory (RAM) device.

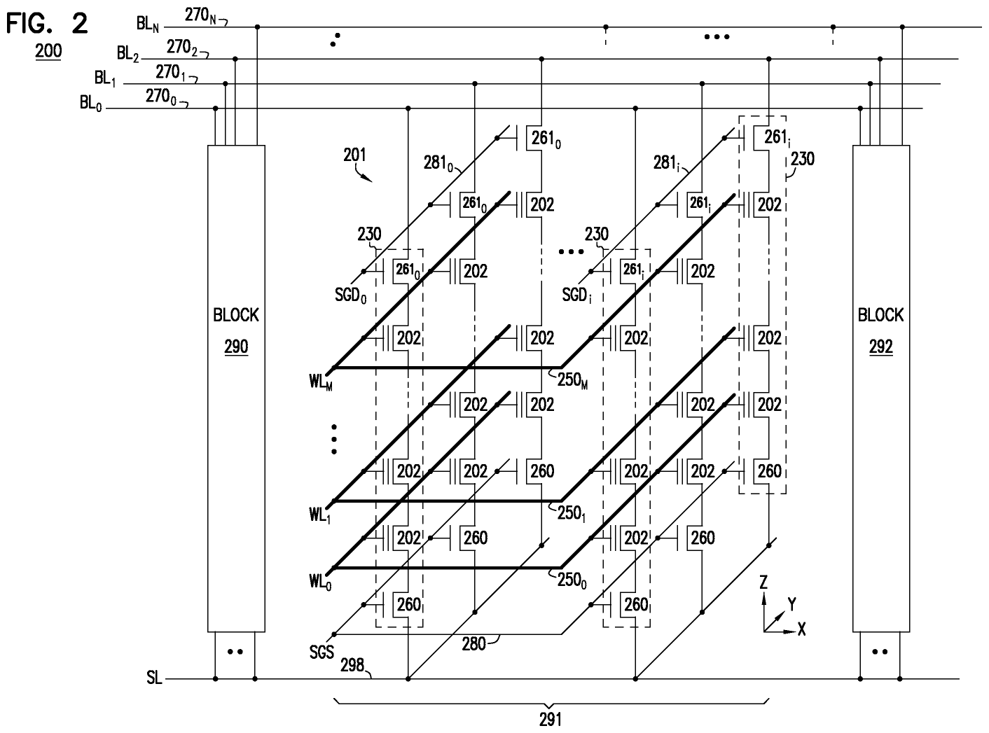

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 21B.

FIG. 2 shows a schematic of a memory device 200 having a memory array 201 and blocks (e.g., memory cell blocks) 290, 291, and 292, according to some embodiments described herein. For simplicity, only detail for elements of block 291 is shown in FIG. 2. Blocks 290 and 292 have similar elements as block 291.

Memory device 200 can include a non-volatile (e.g., NAND flash memory device) or other types of memory devices. Memory device 200 can correspond to memory device 100. For example, memory array (or multiple memory arrays) 201 and blocks 290, 291, and 292 can correspond to memory array 101 and three of blocks 190₀ through 190_{X}, respectively, of memory device 100 of FIG. 1.

As shown in FIG. 2, memory device 200 can include memory cells 202, data lines 270₀ through 270_{N} (270₀-270_{N}), and control gates 250₀ through 250_{M} in block 291. Data lines 270₀-270_{N} can correspond to part of data lines 170 of memory device 100 of FIG. 1. In FIG. 2, label “N” (index N) next to a number (e.g., 270_{N}) represents the number of data lines of memory device 200. For example, if memory device 200 includes 16 data lines, then N is 15 (data lines 270₀ through 270₁₅). In FIG. 2, label “M” (index M) next to a number (e.g., 250_{M}) represents the number of control gates of memory device 200. For example, if memory device 200 includes 128 control gates, then M is 127 (control gates 250₀ through 250₁₂₇). Memory device 200 can have the same number of control gates (e.g., M−1 control gates) among the blocks (e.g., blocks 290, 291, and 292) of memory device 200.

In FIG. 2, data lines 270₀-270_{N} can include (or can be part of) bit lines (e.g., local bit lines) of memory device 200. As shown in FIG. 2, data lines 270₀-270_{N} can carry signals (e.g., bit line signals) BL0 through BL_{N}, respectively. In the physical structure of memory device 200, data lines 270₀-270_{N} can be structured as conductive lines and have respective lengths extending in the Y-direction (e.g., a direction from one memory block to another).

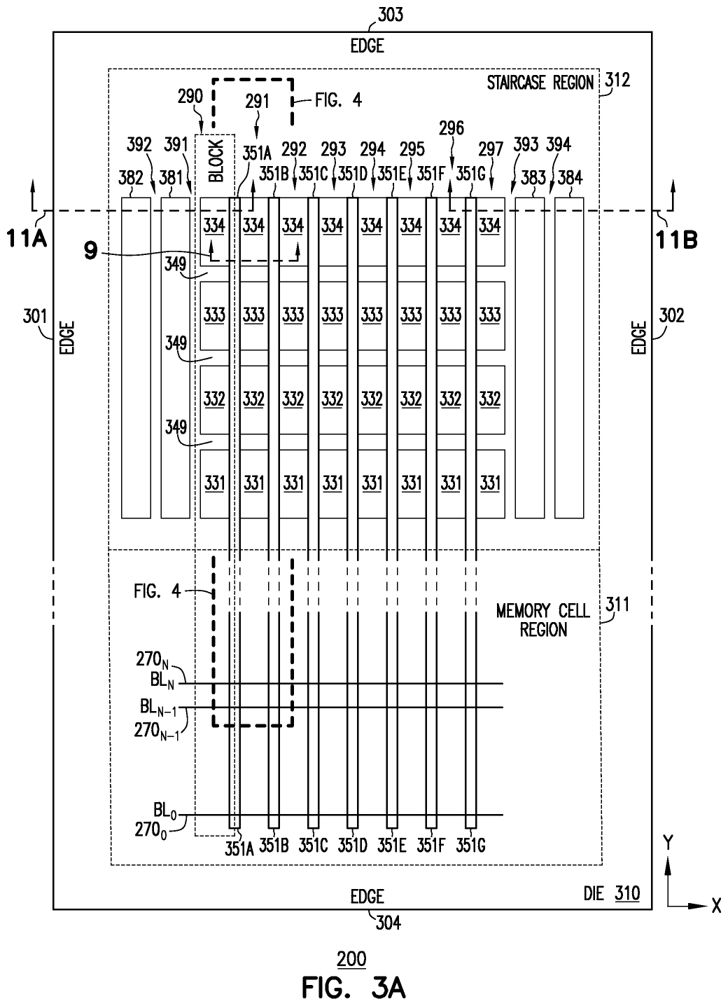

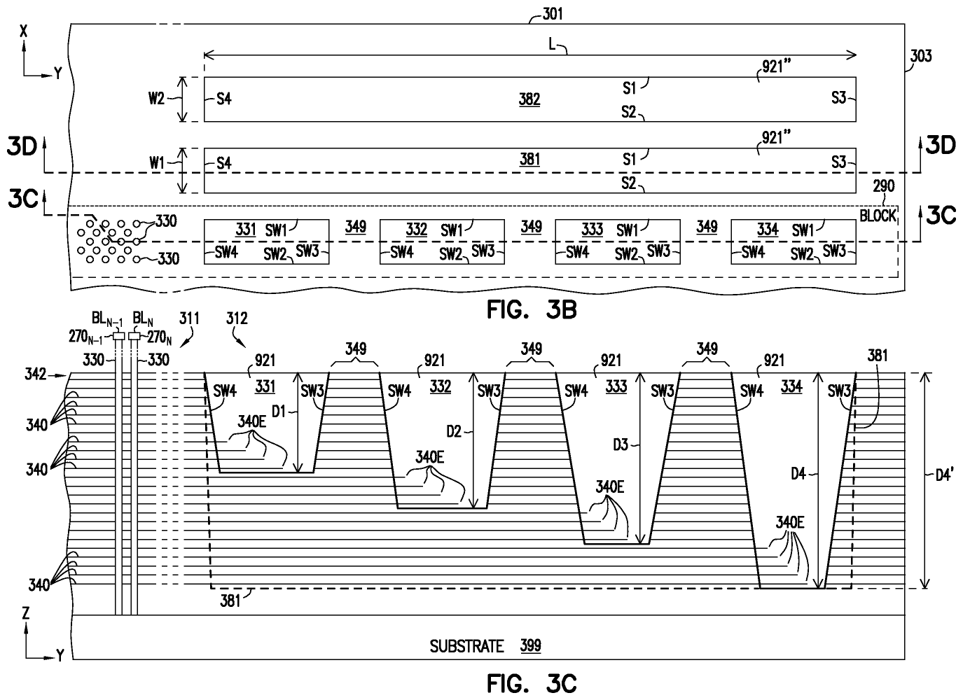

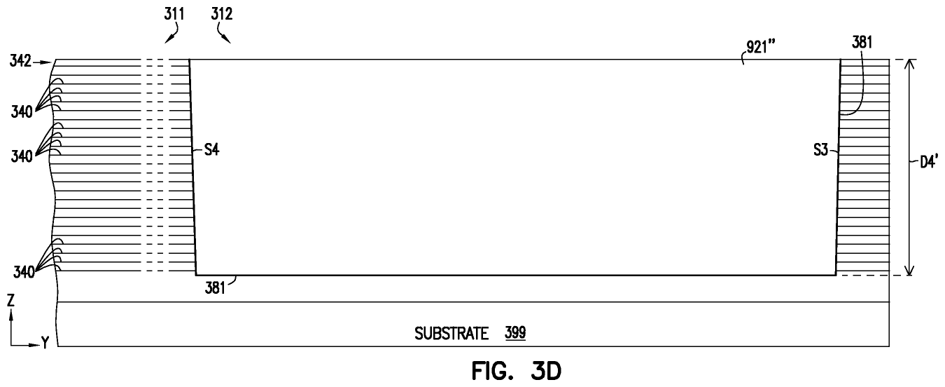

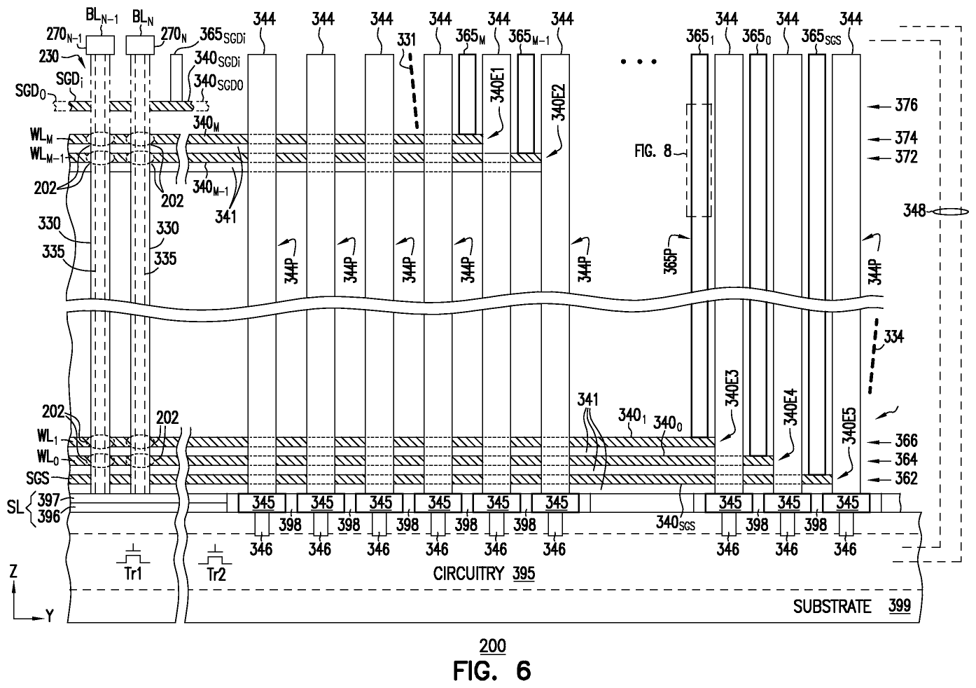

FIG. 2 shows directions X, Y, and Z that can be relative to the physical directions (e.g., dimensions) of the structure of memory device 200. For example, the Z-direction can be a direction perpendicular to (e.g., vertical direction with respect to) a substrate of memory device 200 (e.g., a substrate 399 shown in FIG. 3C and FIG. 6). The Z-direction is perpendicular to the X-direction and Y-direction (e.g., the Z-direction is perpendicular to an X-Y plane of memory device 200).

As shown in FIG. 2, memory cells 202 can be organized into separate blocks (memory cells blocks or blocks of memory cells) such as blocks 290, 291, and 292. FIG. 2 shows memory device 200 including three blocks 290, 291, and 292 as an example. However, memory device 200 can include numerous blocks. The blocks (e.g., blocks 290, 291, and 292) of memory device 200 can share data lines (e.g., data lines 270₀-270_{N}) to carry information (in the form of signals) read from or to be stored in memory cells of h memory cells (e.g., selected memory cells in block 290, 291, or 292) of memory device 200.

Control gates 250₀-250_{M} in block 291 can be part of access lines (e.g., word lines). The access lines (that include control gates 250₀-250_{M}) of memory device 200 can correspond to access lines 150 of memory device 100 of FIG. 1.

Other blocks (e.g., blocks 290 and 292) of memory device 200 can have other control gates associated with memory cells in the other blocks. The other control gates are similar to (or the same as) control gates 250₀-250_{M} of block 291. Blocks 290, 291, and 292 can be accessed separately (e.g., accessed one block at a time). For example, block 291 can be accessed at one time using control gates 250₀-250_{M}, and block 290 or 292 can be accessed at another time using control gates in the respective block.

In the physical structure of memory device 200, control gates 250₀-250_{M} can be formed on different levels (e.g., layers) of memory device 200 in the Z-direction. In this example, the levels (e.g., layers) of control gates 250₀-250_{M} can be formed (e.g., stacked) one level (one layer of material) over another (another layer of material) in the Z-direction.

As shown in FIG. 2, memory cells 202 can be included in respective memory cell strings 230. For simplicity, only three memory cell strings 230 are labeled in FIG. 2. Each of memory cell strings 230 can have series-connected memory cells (e.g., M+1 (e.g., 128) series-connected memory cells) in the Z-direction. In a physical structure of memory device 200, memory cells 202 in each of memory cell strings 230 can be formed (e.g., stacked vertically one over another) in different levels (physical portions) of memory device 200. The levels of memory device 200 can be included in (or can correspond to) respective tiers (stacked one over another in the Z-direction) of memory device 200. In the example of FIG. 2, memory device 200 can include M+1 tiers (e.g., 128 tiers, where M=127) of memory cells and respective control gates. The number of memory cells 202 in each of memory cell strings 230 can be equal to the number of levels (e.g., the number of tiers). Thus, in the example of FIG. 2, there can be 128 levels (layers) of memory cells 202 in the Z-direction.

The number of memory cells 202 in each of memory cell strings 230 can also be equal to the number of levels (e.g., the number of tiers) of control gates (e.g., control gates 250₀-250_{M}) of memory device 200. For example, if each memory cell string 230 has 128 (e.g., M=127) memory cells 202, then there are 128 corresponding levels (e.g., 128 tiers) of control gates 250₀-250_{M} associated with the 128 memory cells.

As shown in FIG. 2, control gates 250₀-250_{M} can carry corresponding signals WL₀-WL_{M}. As mentioned above, control gates 250₀-250_{M} can include (or can be parts of) access lines (e.g., word lines) of memory device 200. Each of control gates 250₀-250_{M} can be part of a structure (e.g., a level) of a conductive material (e.g., a layer of conductive material) located in a level of memory device 200. Memory device 200 can use signals WL₀-WL_{M} to selectively control access to memory cells 202 of block 291 during an operation (e.g., read, write, or erase operation). For example, during a read operation, memory device 200 can use signals WL₀-WL_{M} (associated with memory cells 202 in block 291) to control access to memory cells 202 of block 291 to read (e.g., sense) information (e.g., previously stored information) from memory cells 202 of block 291. In another example, during a write operation, memory device 200 can use signals WL₀-WL_{M} to control access to memory cells 202 of block 291 to store information in memory cells 202 of block 291.

As shown in FIG. 2, memory cells in different memory cell strings in block 291 can share (e.g., can be controlled by) the same control gate in block 291. For example, memory cells 202 (of different memory cell strings 230) coupled to control gate 250₀ can share (can be controlled by) control gate 250₀. In another example, memory cells 202 (of different memory cell strings 230) coupled to control gate 250₁ can share (can be controlled by) control gate 250₁.

Memory device 200 can include a source 298 that can carry a signal (e.g., a source line signal) SL. In the physical structure of memory device 200, source 298 and be called a source structure, a source region, a source plate, or source line. Source 298 can include (e.g., can be formed from) a conductive structure (e.g., conductive region) of memory device 200. The conductive structure of source 298 can include multiple levels (e.g., layers) of conductive materials stacked one over another over a substrate of memory device 200. Source 298 can be common conductive structure (e.g., common source plate or common source region) of blocks 290, 291, and 292. Source 298 can be coupled to a ground connection (e.g., ground plate) of memory device 200. Alternatively, source 298 can be coupled to a connection (e.g., a conductive region) that is different from a ground connection.

As shown in FIG. 2, memory device 200 can include select transistors (e.g., drain select transistors) 261₀ through 261ᵢ (261₀-261ᵢ) and select gates (e.g., drain select gates (SGDs)) 281₀ through 281ᵢ in block 291. Transistors 261₀ can share the same select gate 281₀. Transistors 261ᵢ can share the same select gate 281ᵢ. Select gates 281₀-281ᵢ can carry signals SGD₀ through SGDᵢ (SGD₀-SGDᵢ), respectively.

Transistors 261₀-261ᵢ can be controlled (e.g., turned on or turned off) by signals SGD₀-SGDᵢ, respectively. During a memory operation (e.g., a read or write operation) of memory device 200, transistors 261₀ and transistors 261ᵢ can be turned on one group at a time (e.g., either the group of transistors 261₀ or the group of transistors 261ᵢ can be turned on at a particular time). Transistors 261₀ can be turned on (e.g., by activating signal SGD₀) to couple memory cell strings 230 of block 291 to respective data lines 270₀-270_{N}. Transistors 261ᵢ can be turned on (e.g., by activating signal SGDᵢ) to couple memory cell strings 230 of block 291 to respective data lines 270₀-270_{N}. Transistors 261₀-261ᵢ can be turned off (e.g., by deactivating signals SGD₀-SGDᵢ) to decouple the memory cell strings 230 of block 291 from respective data lines 270₀-270_{N}.

Memory device 200 can include transistors (e.g., source select transistors) 260 in block 291, each of which can be coupled between source 298 and memory cells 202 in a respective memory cell string (one of memory cell strings 230) of block 291. Memory device 200 can include a select gate (e.g., source select gate (SGS)) 280 that can be shared by transistors 260. Transistors 260 can be controlled (e.g., turned on or turned off) by the same signal, such as SGS signal (e.g., source select gate signal) provided on select gate 280. During a memory operation (e.g., a read or write operation) of memory device 200, transistors 260 can be turned on (e.g., by activating an SGS signal) to couple memory cell strings 230 to source 298. Transistors 260 can be turned off (e.g., by deactivating the SGS signal) to decouple memory cell strings 230 from source 298.

Memory device 200 includes other components, which are not shown in FIG. 2 so as not to obscure the example embodiments described herein. Some of the structures of memory device 200 are described below with reference to FIG. 3A through FIG. 11B. For simplicity, detailed description of the same element among the drawings (FIG. 1 through FIG. 11B) is not repeated.

FIG. 3A shows a top view of a structure of memory device 200 including a die 310 that includes memory cell region 311, a staircase region 312, dielectric structures (e.g., block dividers) 351A through 351G between respective blocks 290 through 297, and trench structures 381, 382, 383, and 384, according to some embodiments described herein.

In the figures (drawings) herein, similar or the same elements of memory device 200 of FIG. 2 and other figures (e.g., FIG. 3A through FIG. 21B) are given the same labels. Detailed descriptions of similar or the same elements may not be repeated from one figure to another figure. For simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements shown in the drawings described herein are not scaled.

Die 310 can include a semiconductor (e.g., silicon) die. Die 310 can have structures and circuitry formed thereon (or formed therein) that are included in memory device 200. As shown in FIG. 3A, die 310 can include an edge (e.g., left edge) 301 on a side (e.g., left side) of memory device 200, an edge 302 (e.g., right edge) on a side (e.g., right side) of memory device 200, an edge (e.g., top edge) 303 on a side (e.g., top side) of memory device 200, and an edge (e.g., bottom edge) 304 on a side (e.g., bottom side). As shown in FIG. 3A, edges 301 and 302 are opposite from each other in the X-direction. Edges 303 and 304 are opposite from each other in the Y-direction.

As shown in FIG. 3A, blocks (memory cell blocks) 290 through 297 of memory device 200 can be located side-by-side from one block to another (e.g., adjacent each other) in the X-direction. Each of the blocks 290 through 297 has a width in the X-direction and a length in the Y-direction. Eight blocks 290 through 297 are shown as an example. Memory device 200 can include numerous blocks. Blocks 290, 291, and 292 of FIG. 3A are schematically shown and described above with reference to FIG. 2. As shown in FIG. 3A, block 290 is nearer edge 301 than other blocks. Block 290 is nearer edge 302 than other blocks. Block 290 can be called the left-most block in the X-direction. Block 297 can be called the right-most block in the X-direction. Some of the blocks of memory device 200 may be dummy blocks (dummy memory blocks) that have similar structures and memory cells as the normal blocks (functional blocks). However, the dummy blocks may not be used in memory device 200. The dummy blocks may be the blocks nearest trench structures 381 and 383. For example, blocks 290 and 297 may be dummy blocks.

In FIG. 3A, dielectric structures 351A through 351G can be formed to divide (e.g., separate) memory device 200 into physical blocks (e.g., blocks 290 through 297). For example, dielectric structure 351A can separate block 291 from block 290. Dielectric structure 351B can separate block 291 from block 292. Dielectric structures 351A through 351G can have lengths extending in the Y-direction. The length of each of dielectric structures 351A through 351G can be the same as (e.g., equal to) the lengths of an adjacent block (or adjacent blocks).

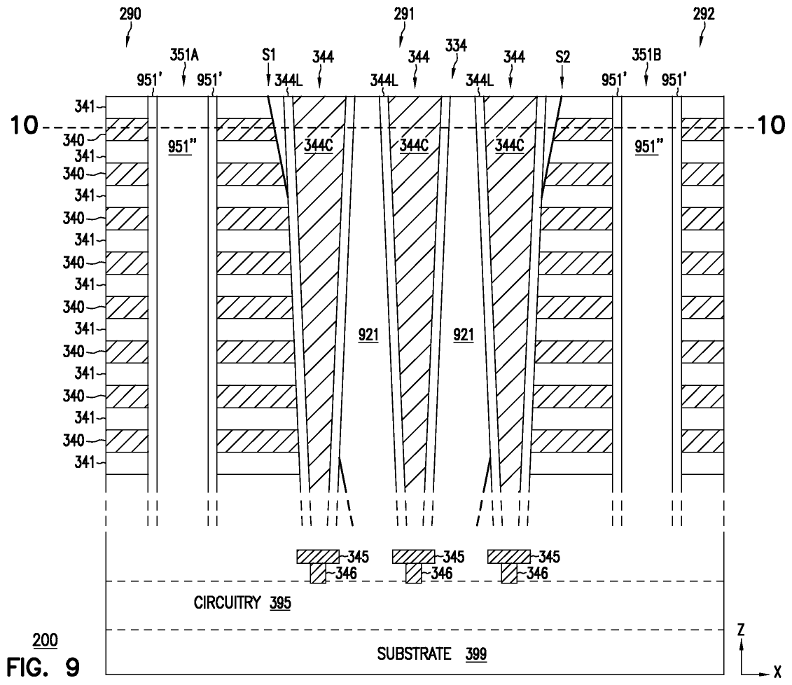

Each of dielectric structures 351A through 351G can include (or can be formed in) a slit between two adjacent blocks. The slit can have sidewalls (e.g., edges) opposing each other in the X-direction and adjacent two respective blocks. The slit can include (or can be) a trench having a depth in the Z-direction. For example, dielectric structure 351B can be formed (e.g., located) in a slit between blocks 290 and 291, in which the slit can have opposing sidewalls adjacent respective blocks 290 and 291. In another example, dielectric structure 351C can be formed in a slit between blocks 291 and 292, in which the slit can have opposing sidewalls adjacent respective blocks 291 and 292. Other dielectric structures 351A and 351D through 351G can be located adjacent respective blocks shown in FIG. 3A. Each of dielectric structures 351A through 351G can include dielectric materials (e.g., dielectric materials 951′ and 951″ in FIG. 9) formed in a respective slit.

As shown in FIG. 3A, data lines 270₀ through 270_{N} (associated with signals BL₀ through BL_{N}) of memory device 200 can be located over blocks 290 through 297 (with respect to the Z-direction). Data lines 270₀ through 270_{N} can have respective lengths extending in the X-direction. Data lines 270₀ through 270_{N} can extend over (e.g., on top of) and across (in the X-direction) blocks 290 through 297 in memory cell region 311. Data lines 270₀ through 270_{N} can be shared by blocks 290 through 297.

Staircase region 312 of memory device 200 can be adjacent memory cell region (e.g., memory array region) 311 in the Y-direction. Staircase region 312 can include staircase structures 331, 332, 333, and 334 in each of blocks 290 through 297. Staircase structures 331, 332, 333, and 334 are part of memory device 200 where conductive contacts (described in more detail below) can be formed to provide electrical connections (e.g., signals) to respective select gates and control gates (e.g., shown in FIG. 2 as select gates 280, 281₀ and 281ᵢ and control gates 250₀ through 250_{M}) in respective blocks 290 through 297 of memory device 200.

FIG. 3A shows memory device 200 having four staircase structures 331, 332, 333, and 334 in each block as an example. However, the number of staircase structures in each block can be different from four.

FIG. 3A shows memory device 200 having a single staircase region 312 as an example. However, memory device 200 can include multiple staircase regions like staircase region 312. For example, memory device 200 can include an additional staircase region (not shown in FIG. 3A) located between memory cell region 311 and edge 304 of die 310.

As shown in FIG. 3A, trench structures 381 and 382 can be located (e.g., formed) between edge 301 and block 290. Trench structure 381 is adjacent staircase structures 331, 332, 333, and 334 of block 290 and is separated from staircase structures 331, 332, 333, and 334 of block 290 by a region 391. Trench structures 381 and 382 are separated from each other by a region 391.

As shown in FIG. 3A, trench structures 383 and 384 can be located (e.g., formed) between edge 302 and block 297. Trench structure 384 is adjacent staircase structures 331, 332, 333, and 334 of block 297 and is separated from staircase structures 331, 332, 333, and 334 of block 297 by a region 393. Trench structures 381 and 382 are separated from each other by a region 394.

Each of trench structures 381, 382, 383, and 384 can have a length (e.g., length L in FIG. 3B) extended continuously in the Y-direction, which is also the direction from one staircase structure to another staircase structure among staircase structures 331, 332, 333, and 334. As shown in FIG. 3A, the length of each of trench structures 381, 382, 383, and 384 may extend within staircase region 312 and may not extend to memory cell region 311 the Y-direction. Thus, the length of each of trench structures 381, 382, 383, and 384 can be less than the length of each of dielectric structures 351A through 351G.

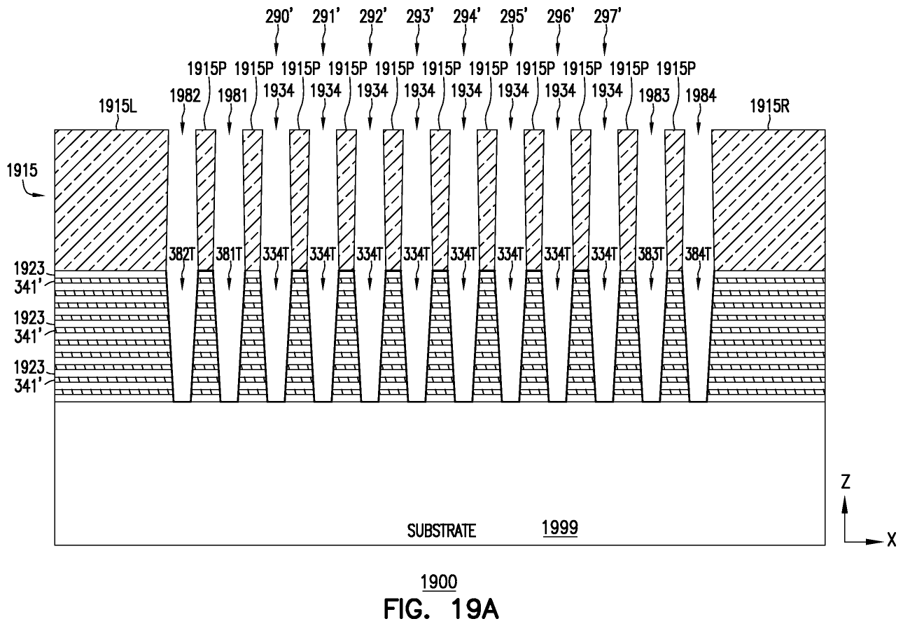

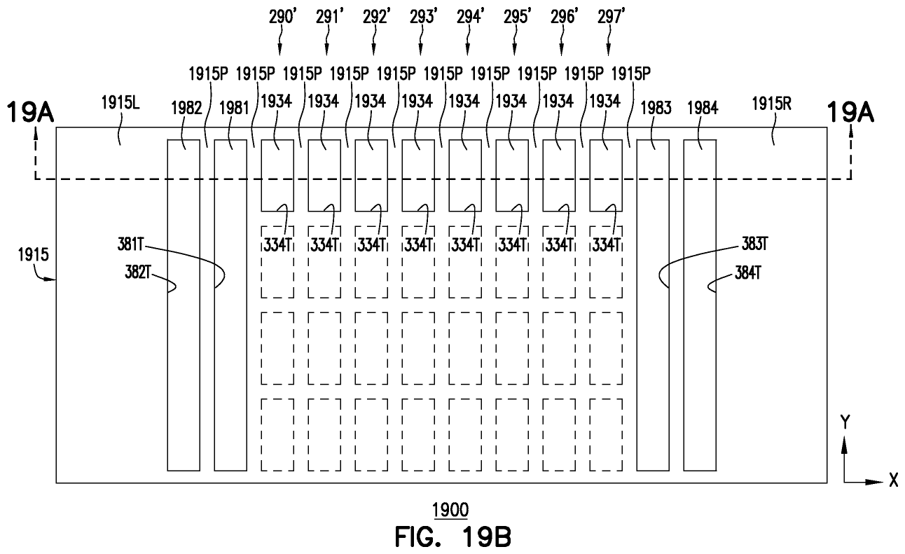

As described in more detail below (with reference to FIG. 19A and FIG. 19B), trench structures 381 and 382 are formed to improve the structures of staircase structures of at least one block (e.g., block 290) near edge 301 of die 310. Trench structures 383 and 384 are formed to improve the structures of staircase structures of the at least one block (e.g., block 297) near edge 302 of die 310.

FIG. 3A shows memory device 200 including two trench structures (e.g., trench structures 381 and 382) between edge 301 and block 290 and two trench structures (e.g., trench structures 383 and 384) between edge 302 and block 297 as an example. However, memory device 200 can include fewer than two trench structures or more than two trench structures between edge 301 and adjacent staircase structures 331, 332, 333, and 334 of a block near edge 301 (e.g., a dummy block or a normal block (e.g., block 290)). Similarly, memory device 200 can include fewer than two trench structures or more than two trench structures between edge 302 and adjacent staircase structures 331, 332, 333, and 334 of a block near edge 302 (e.g., a dummy block or a normal block (e.g., block 297)).

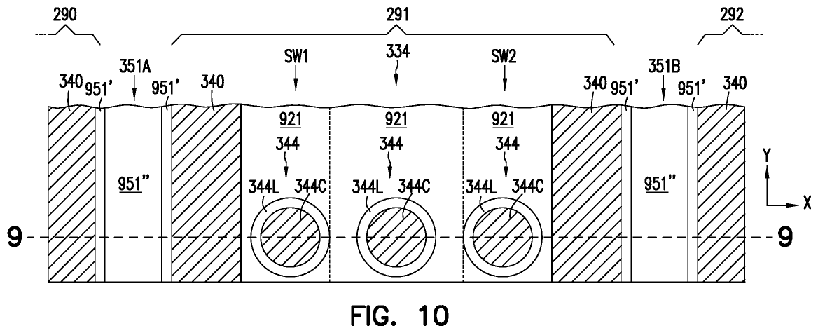

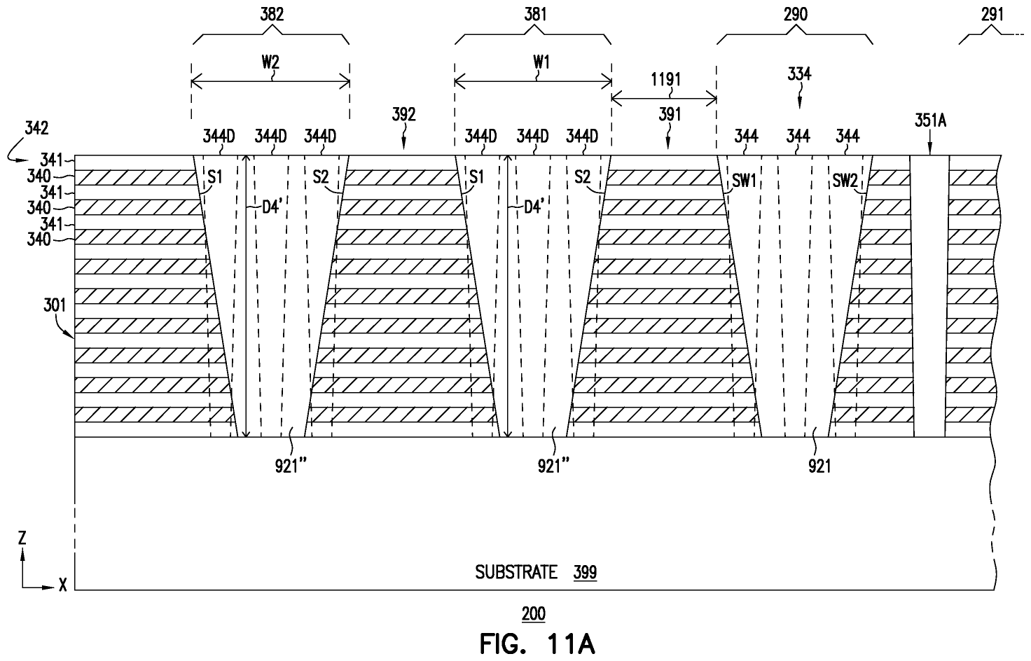

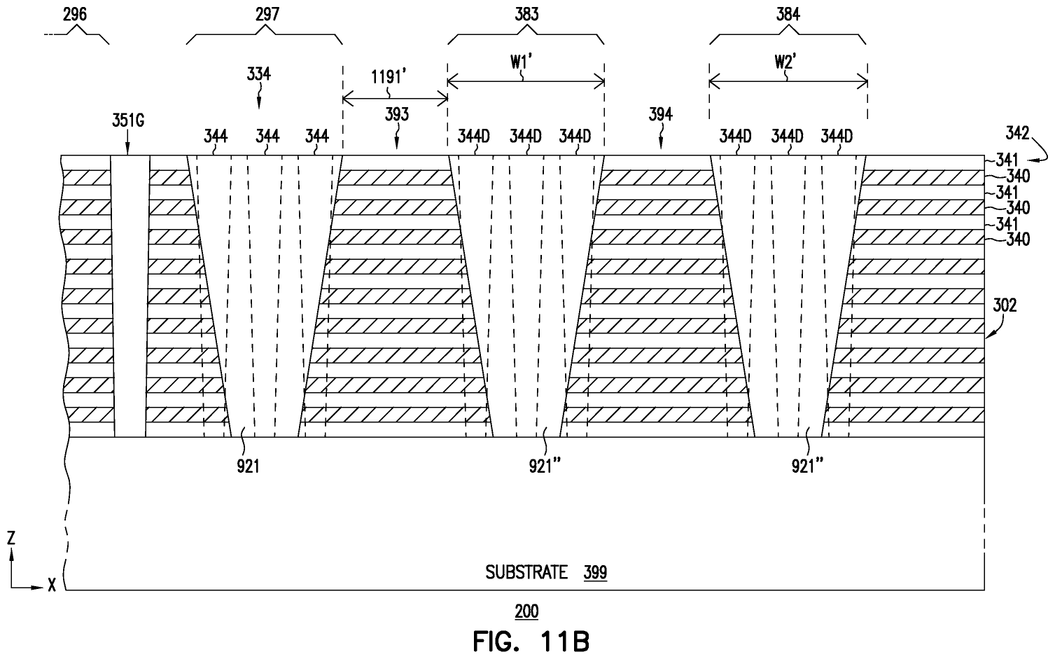

In FIG. 3A, a portion labeled “FIG. 4” is shown in detail in FIG. 4. In FIG. 3A, a portion (e.g., side view in the X-Z direction) of memory device 200 along lines 10, 11A, and 11B are shown in (and described below with reference to) FIG. 10, FIG. 11A, and FIG. 11B, respectively.

FIG. 3B, FIG. 3C, and FIG. 3D show some detail of a portion of a top view of memory device 200 of FIG. 3A. FIG. 3B shows a top view of a portion of memory device 200 of FIG. 3A including staircase structures 331, 332, 333, and 334 of block 290, and trench structures 381 and 382. FIG. 3C shows a side view (e.g., cross-section) of memory device 200 of FIG. 3B along line 3C-3C. FIG. 3D shows a side view (e.g., cross-section) of memory device 200 of FIG. 3B along line 3D-3D.

As shown in FIG. 3C, memory device 200 can include levels of conductive materials 340 interleaved with levels of dielectric materials (not labeled) in the Z-direction. For simplicity, each level of conductive material 340 is shown as a line in FIG. 3C. The levels of conductive materials 340 and the levels of dielectric materials (not labeled) are included in tiers (not labeled) of memory device 200. The tiers can be located (e.g., stacked) one over another in the Z-direction over substrate 399. Substrate 399 can include semiconductor (e.g., silicon) substrate.

As shown in FIG. 3C, each of staircase structures 331, 332, 333, and 334 can include a trench (not labeled) formed in the tiers of memory device 200. Each of staircase structures 331, 332, 333, and 334 can include a dielectric material (or dielectric materials) 921 formed (e.g., filled) therein. Dielectric material 921 can include silicon dioxide or other dielectric materials. For simplicity, FIG. 3B and FIG. 3C omit other elements (e.g., vertical conductive contacts and contact structures) of memory device 200 at staircase structures 331, 332, 333, and 334.

As shown in FIG. 3B, each of staircase structures 331, 332, 333, and 334 can include sidewalls SW1 and SW2 opposite from each other in the X-direction, and sidewalls SW3 and SW4 opposite from each other in the Y-direction. Sidewalls SW1 and SW2 can be parallel to length in the Y-direction of respective staircase structure. Sidewalls SW3 and SW4 can be parallel to width in the X-direction of respective staircase structure.

As shown in FIG. 3C, staircase structures 331, 332, 333, and 334 can have depths D1, D2, D3, and D4, respectively, in the Z-direction. Depths D1, D2, D3, and D4 can be measured (e.g., in nanometer unit) at reference level, such as a level 342. Level 342 can correspond to a level of a selected tier (e.g., a topmost tier or a tier near the topmost tier) among the tiers memory device 200. As shown in FIG. 3C, depths D1, D2, D3, and D4 are different from (unequal to) each other. Depth D4 is greater than depth D3. Depth D3 is greater than depth D2. Depth D2 is greater than depth D1. Depth D1 can be the smallest depth (e.g., shallowest) among the depths (e.g., depths D1 through D4) of the staircase structures of memory device 200. Depth D4 can be the greatest depth (e.g., deepest) among the depths (e.g., depths D1 through D4) of the staircase structures of memory device 200.

As shown in FIG. 3C, part of the levels of conductive materials 340 in the tiers of memory device 200 can be removed (e.g., etched) at the locations of staircase structures 331, 332, 333, and 334. The remaining portion (FIG. 3C) of the levels of conductive materials 340 at respective staircase structures 331, 332, 333, and 334 can have respective edges 340E. Edges 340E at a particular staircase structure can form part of that particular staircase structure. As shown in FIG. 3B and FIG. 3C, memory device 200 can have regions 349 between respective trenches of staircase structures 331, 332, 333, and 334. Regions 349 can be called crest regions where the materials in the portions of the tiers of memory device 200 at regions 349 are not removed (e.g., not etched) when other portions of the tiers (e.g., portions at the locations of staircase structures 331, 332, 333, and 334) are removed to form the trenches of staircase structures 331, 332, 333, and 334.

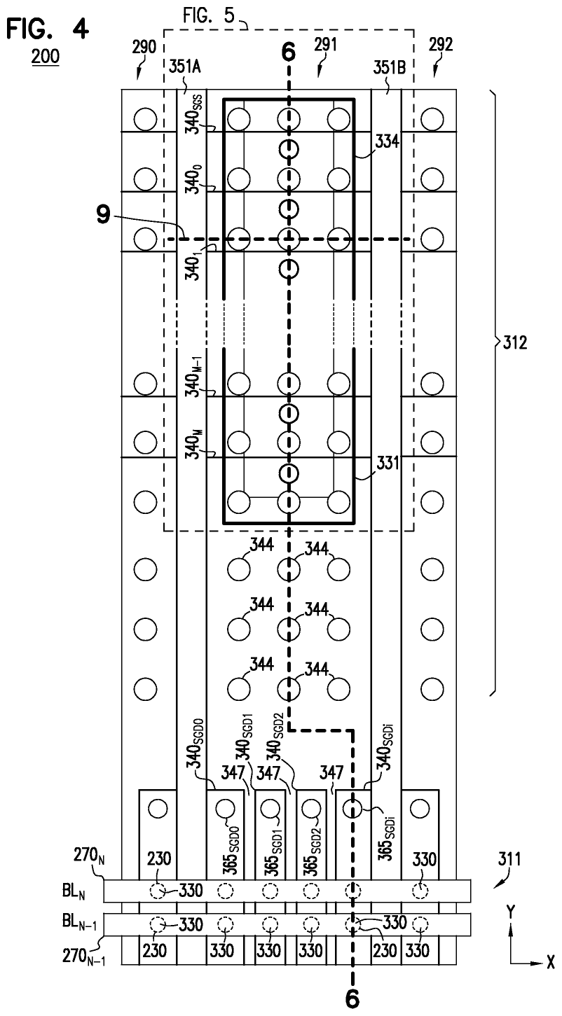

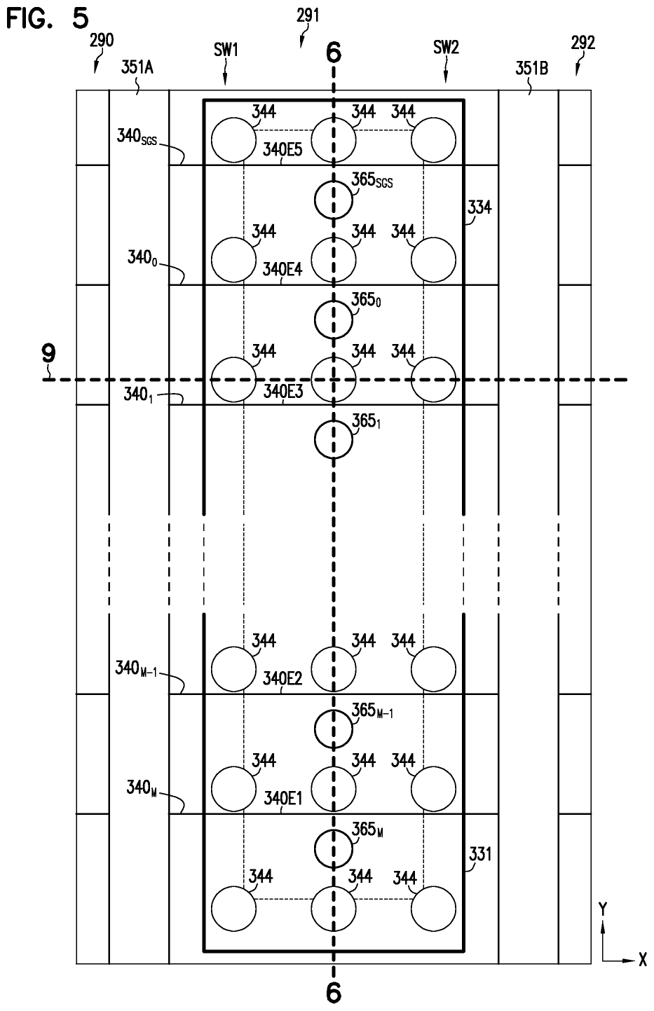

For simplicity, FIG. 3B and FIG. 3C do not show conductive contacts (e.g., local word line contacts) of memory device 200 that are coupled to respective levels of conductive materials 340 at locations near edges 340E. The conductive contacts (not shown in FIG. 3C) can include conductive contacts 365_{SGS}, 365₀, 365₁, 365_{M-1}, 365_{M}, and 365_{SGD0} through 365_{SGDi} that are shown in other figures (e.g., FIG. 4, FIG. 5, and FIG. 6). Such conductive contacts can be formed to provide electrical connections (e.g., signals) to respective select gates and control gates (e.g., shown in FIG. 2 as select gates 280, 281₀ and 281ᵢ and control gates 250₀ through 250_{M}) in respective blocks 290, 291, and 292 of memory device 200. FIG. 3B and FIG. 3C also do not show other structures (e.g., contact structures 344 in FIG. 6, described below) associated with staircase structures 331, 332, 333, and 334.

As shown in FIG. 3B and FIG. 3C, memory device 200 can include pillars 330 in block 290 in memory cell region 311. Pillars 330 are memory cell pillars (shown in detail in FIG. 6) that can extend (e.g., extend vertically) in the Z-direction. Each pillar 330 is coupled to a respective data line (e.g., data line 270_{N} or 270_{N-1}).

As shown in FIG. 3B, each of trench structures 381 and 382 can be formed in the tiers (which include levels of conductive materials 340) of memory device 200. Each of trench structures 381 and 382 can include a dielectric material (or dielectric material) 921″ formed (e.g., filled) in the trench structure. Dielectric material 921″ can be similar to (or the same as) dielectric material (e.g., silicon dioxide) 921 in staircase structures 331, 332, 333, and 334. Memory device 200 may include other elements (e.g., dummy vertical conductive contacts and dummy contact structures) formed in trench structure 381 (and other trench structures). Such other elements are not shown in FIG. 3B and FIG. 3C for simplicity.

As shown in FIG. 3B, each of trench structures 381 and 382 can include sidewalls S1 and S2 opposite from each other in the X-direction, and sidewalls S3 and S4 opposite from each other in the Y-direction. Sidewall S2 is between sidewall S1 staircase structures 311, 332, 333, and 334 of block 290.

As shown in FIG. 3D, trench structure 381 can include depths D4′ in the Z-direction. Trench structures 381 and 382 can have the same depth (e.g., depth D4′). Depth D4′ can be similar to (or the same as) depth D4. As shown in FIG. 3C, depth D4′ can be greater than each of the depths (e.g., depths D1, D2, and D3) of the staircase structures (e.g., staircase structures 331 through 334) of memory device 200 except one (e.g., except depth D4).

Each of staircase structures 331, 332, 333, and 334 can have a length (not labeled) in the Y-direction. The lengths of staircase structures 331, 332, 333, and 334 can be the same or can be different. For example, the length of staircase structure 334 can be greater than the length of staircase structure 333. The length of staircase structure 334 can be greater than the length of staircase structure 332. The length of staircase structure 332 can be greater than the length of staircase structure 331. Thus, the length of staircase structures 331 and 334 can be the greatest and smallest, respectively, among the lengths of staircase structures 331, 332, 333, and 334.

As shown in FIG. 3B, each of trench structures 381 and 382 can have length L that extends (extends continuously) in the Y-direction, which is also the direction from one staircase structure to another among staircase structures 331, 332, 333, and 334. Length L is greater than the length of each of staircase structures 331, 332, 333, and 334. Length L can be greater than the combined lengths (the sum of the lengths) of staircase structures 331, 332, 333, and 334 in the Y-direction.

As shown in FIG. 3B, trench structures 381 and 382 and have widths W1 and W2, respectively. Width W1 and Width W2 can be the same (or substantially the same). Each of staircase structures 331, 332, 333, and 334 (FIG. 3B) can have a width (not labeled) in the X-direction that can be similar to (e.g., equal to) width W1 or W2 (FIG. 3B).

Trench structures 383 and 384 (FIG. 3A) can have respective widths in the X-direction like widths W1 and W2, respectively, in FIG. 3B and respective lengths in the Y-direction like length L in FIG. 3B.

FIG. 4 shows some detail of a top view of the portion labeled “FIG. 4” in FIG. 3A. In FIG. 4, the portion labeled “FIG. 5” is shown in an enlarged view (with additional labels) in FIG. 5. A portion (e.g., side view in the Y-Z direction) of memory device 200 along line 6 in FIG. 4 and FIG. 5 is shown in FIG. 6 (described below). A portion (e.g., side view in the X-Z direction) of memory device 200 along line 9 in FIG. 4 and FIG. 5 is shown in FIG. 9 (described below).

FIG. 4 and FIG. 5 shows a portion of each of staircase structures 331 and 334 and omit staircase structures 332 and 333 for simplicity. However, staircase structures 332 and 333 can include similar elements like staircase structures 331 and 334 shown in FIG. 4 and FIG. 5. As described above with reference to FIG. 3B and FIG. 3C, each of staircase structures 331, 332, 333, and 334 can have opposing sidewalls SW1 and SW2 in the X-direction, and opposing sidewalls SW3 and SW4 in the Y-direction. FIG. 4 and FIG. 5 show a portion of sidewall (e.g., left sidewall) SW1 and a portion of sidewall (e.g., right sidewall) SW2 of each of staircase structures 331 and 334.

The following description refers to FIG. 4 and FIG. 5. As shown in FIG. 4, memory device 200 can include pillars 330 (shown in top view) in each of block 290 through 297. Each pillar 330 is part of a respective memory cell string 230 (also schematically shown in FIG. 2). Memory device 200 can include conductive contacts 365₀ through 365_{M}, which can be called word line contacts (e.g., local word line contacts). For simplicity, only conductive contacts 365₀, 365₁, 365_{M-1}, and 365_{M} (labeled in FIG. 5) among conductive contacts 365₀ through 365_{M} (365₀-365_{M}) are shown in FIG. 4 and FIG. 5 and other figures described herein. Conductive contacts between conductive contacts 365₁ through 365_{M-1} are not shown.

As shown in FIG. 4, pillars (memory cell pillars) 330 can be located under (below) and coupled to respective data lines (only data lines 270_{N-1} and 270_{N} are shown). Memory cells 202 of a memory cell string can be located (e.g., can be formed vertically) long the length (shown in FIG. 6) of a corresponding pillar 330. Pillars 330 (and associated memory cell strings) of blocks 290 through 297 can share data lines 270₀ through 270_{N}.

As mentioned above, memory device 200 can include contact structures 344. For simplicity, FIG. 4 does not give labels for all contact structures 344. As shown in FIG. 4 and FIG. 5, contact structures 344 can be located (e.g., can be formed) in respective rows in which each row can include many contact structures 344 in the Y-direction. FIG. 4 and FIG. 5 show block 291 including three rows (e.g., left, middle, and right rows parallel to the Y-direction) of contact structures 344 as an example, such that there can be three adjacent contact structures 344 in the X-direction (e.g., three contact structures 344 lining up in the X-direction). However, block 291 of memory device 200 can include a different number of rows of contact structures 344, such that the number adjacent contact structures 344 (e.g., that line up) in the X-direction can be different from three.

As shown in FIG. 5, contact structures 344 and conductive contacts 365_{SGS} and 365₀-365_{M} can be adjacent each other. For example, one conductive contact (e.g., conductive contact 365₀) can be adjacent and between two contact structures 344 in the Y-direction. One contact structure 344 (e.g., middle contact structure 344 in a block) can be adjacent and between two contact structures (e.g., conductive contacts 365₀ and 365₁) in the Y-direction. FIG. 4 and FIG. 5 show block 291 including one row of conductive contacts 365_{SGS} and 365₀-365_{M} (labeled in FIG. 5) parallel to the Y-direction as an example. However, block 291 of memory device 200 can include a different number of rows of conductive contacts 365_{M} parallel to the Y-direction.

As shown in FIG. 4 and FIG. 5 (e.g., viewing from a direction perpendicular to the X-Y plane (e.g., top view)), conductive contacts 365_{SGS}, 365₀-365_{M}, and 365_{SGD0}-365_{SGDi} can have a circular shape. For example, the boundary of a cross-section (e.g., from a top view) of each conductive contact (e.g., conductive contact 365_{M}) has a circular boundary when viewed from a direction perpendicular to the X-Y plane.

FIG. 4 and FIG. 5 show an example where each of contact structures 344 can also have a circular shape. For example, the boundary of a cross-section (e.g., from a top view) of each contact structure 344 has a circular boundary when viewed from a direction perpendicular to the X-Y plane. However, the boundary of a cross-section of each of contact structures 344 can have a shape different from a circular shape. As an example, each of contact structures 344 can have an oval or oval-like shape, a rectangular or rectangular-like shape (e.g., rectangular having rounded corners), or other shapes.

As mentioned above, conductive contacts 365_{SGS}, 365₀-365_{M}, and 365_{SGD0}-365_{SGDi} in FIG. 4 can be formed to provide electrical connections (e.g., signals) to respective select gates and control gates (e.g., select gates 280, 281₀ and 281ᵢ and control gates 250₀ through 250_{M} of FIG. 2) of memory device 200.

Contact structures 344 in FIG. 4 can be formed to provide electrical connections (e.g., to form part of respective conductive paths) between circuitry (e.g., circuitry 395 in FIG. 9) of memory device 200 and other elements of memory device 200.

As shown in FIG. 4 and FIG. 5, memory device 200 can include conductive materials 340_{SGS}, 340₀ through 340_{M}, and 340_{SGD0}, 340_{SGDi}, 340_{SGD2}, and 340_{SGDi} (340_{SGD0} through 340_{SGDi} or 340_{SGD0}-340_{SGDi}) in block 291 that can form (e.g., can be materials included in) respective select gate (e.g., source select gate) 280, control gates 250₀ through 250_{M}, and select gates (e.g., drain select gates) 280₀ and 280ᵢ (in FIG. 2). For simplicity, only conductive materials 340₀, 340₁, 340_{M-1}, and 340_{M} among conductive materials 340₀ through 340_{M} (340₀-340_{M}) are shown in FIG. 4 and other figures described herein. Conductive materials 340_{SGS} and 340₀ through 340_{M} are shown in FIG. 3C as some of conductive materials 340.

In FIG. 4, conductive materials (e.g., four separate conductive materials) 340_{SGD0}, 340_{SGD1}, 340_{SGD2}, and 340_{SGDi} can form four respective drain select gates of block 291. The drain select gates formed by conductive materials 340_{SGD1} and 340_{SGD2} in FIG. 4 are not shown in FIG. 2. As shown in FIG. 4, conductive materials 340_{SGD0}-340_{SGDi} (FIG. 4) can be electrically separated from each other by a gap 347 (which can be filled with a dielectric material (or materials)). For simplicity, FIG. 4 does not give labels for other conductive materials that form respective select gates and control gates of blocks 290 and 292.

The four conductive materials 340_{SGD0}, 340_{SGD1} and 340_{SGD2} and 340_{SGDi} included in four respective drain select gates on the same level in block 291 can be associated with four respective sub-blocks of block 291. FIG. 4 shows an example of memory device 200 including four drain select gates in each block (e.g., block 291) formed by four corresponding conductive materials 340_{SGD0}, 340_{SGD1}, 340_{SGD2}, and 340_{SGDi} on the same level (e.g., level 376 in FIG. 6). However, the number of drain select gates on the same level in a block of memory device 200 can be different from four. For example, the number of drain select gates on the same level in a block can be based on (e.g., equal to) the number of sub-blocks in a block.

FIG. 6 shows a portion (e.g., side view in the Y-Z direction) of memory device 200 along line 6 in FIG. 4 and FIG. 5. As shown in FIG. 6, memory device 200 can include levels 362, 364, 366, 372, 374, and 376 that are physical layers (e.g., portions) in the Z-direction of memory device 200. Conductive materials 340_{SGS}, 340₀-340_{M}, and 340_{SGD0}-340_{SGDi} (also shown in top view in FIG. 5) can be located (e.g., stacked) one level (e.g., one layer) over another in respective levels 362, 364, 366, 372, 374, and 376 (FIG. 6) in the Z-direction. Conductive materials 340_{SGS}, 340₀-340_{M}, and 340_{SGD0}-340_{SGDi} can also be called levels of conductive materials 340_{SGS}, 340₀-340_{M}, and 340_{SGD0}-340_{SGDi}. As shown in FIG. 6, conductive materials 340_{SGD0}-340_{SGDi} can be located on the same level (e.g., level 376). Conductive materials 340_{SGS} and 340₀ through 340_{M} are also shown in FIG. 3B as part of the levels of conductive materials 340.

Conductive materials 340_{SGS}, 340₀-340_{M}, and 340_{SGDi} can interleave with dielectric materials 341 in the Z-direction. Conductive materials 340_{SGS}, 340₀-340_{M}, and 340_{SGDi} can include metal (e.g., tungsten or other metal), other conductive materials, or a combination of conductive materials. Dielectric materials 341 can include silicon dioxide. Dielectric materials 341 can also be called levels of dielectric materials, which are formed to electrically separate (in the Z-direction) the control gates (formed by conductive materials 340₀-340_{M}) from each other and from other elements (e.g., source select gate and drain select gate) of memory device 200.

Signals SGS, WL₀, WL₁, WL_{M-1}, WL_{M}, SGD₀, and SGDᵢ in FIG. 6 associated with respective conductive materials in FIG. 6 are the same signals shown in FIG. 2. Conductive material 340_{SGS} in FIG. 6 can form select gate 280 (associated with signal SGS) of FIG. 2. Conductive materials 340₀-340_{M} in FIG. 6 can form control gates 250₀ through 250_{M} (associated with signals WL₀, WL₁, WL_{M-1}, and WL_{M}, respectively) of FIG. 2. Conductive material 340_{SDG0} and 340_{SGDi} (associated with signals SGD₀ and SGDᵢ) in FIG. 6 can form select gates 281₀ and 281ᵢ respectively, of FIG. 2.

FIG. 6 shows an example of memory device 200 including one level of conductive materials 340_{SGS} that forms a select gate (e.g., source select gate associated with signal SGS). However, memory device 200 can include multiple levels (similar to level 362) of conductive materials (e.g., multiple levels of conductive material 340_{SGS}) located under (in the Z-direction) the level of conductive materials 340₀ (e.g., below level 364) to form multiple source select gates of memory device 200.

FIG. 6 shows an example of memory device 200 including one level (e.g., level 376) of multiple drain select gates (on the same level, formed by respective conductive materials 340_{SGD0}-340_{SGDi}). However, memory device 200 can include multiple levels (e.g., similar to level 376) in which each of such multiple levels can include multiple drain select gates (e.g., four drain select gates in each of the multiple levels).

Each of staircase structures 331 and 334 is partially shown in FIG. 6 for simplicity. As shown in FIG. 6, respective portions (e.g., end portions) of conductive materials 340_{SGS} and 340₀-340_{M} and their respective edges (e.g., steps (or risers)) 340E1, 340E2, and 340E3, 340E4, and 340E5 can collectively form part of a staircase structure. Edges 340E1, 340E2, and 340E3, 340E4, and 340E5 are part of edges 340E shown in FIG. 3C. As shown in FIG. 6, conductive materials 340_{M} and 340_{M-1} and their respective edges 340E1 and 340E2 can collectively form part of staircase structure 331. In another example, conductive materials 340₁, 340₀, and 340_{SGS} and their respective edges 340E3, 340E4, and 340E5 can collectively form part of staircase structure 334. As shown in FIG. 6, dielectric materials 341 can also include edges (not labeled) adjacent (e.g., aligned in the Z-direction with) respective edges 340E1, 340E2, and 340E3, 340E4, and 340E5. Thus, each of staircase structures 331 and 334 can also be formed in part by portions and edges (e.g., edges that are aligned with edges 340E1, 340E2, and 340E3, 340E4, and 340E5) of dielectric materials 341.

FIG. 6 also shows tiers of memory device 200 on respective levels 362, 364, 366, 372, 374, and 376. A tier of memory device 200 can include a level of conductive material (e.g., conductive material 340₁) and an adjacent level of dielectric material 341 (e.g., dielectric material 341 between conductive materials 340₀ and 340₁). As shown in FIG. 6, the tiers can be located (e.g., stacked) one over another in the Z-direction over substrate 399 on respective levels 362, 364, 366, 372, 374, and 376.

FIG. 6 shows some of tiers of memory cells 202. Each tier of memory cells 202 can have respective memory cells 202 that are located on the same level (same tier) with respect to the Z-direction. For example, FIG. 6 shows four tiers of memory cells 202 located on four respective tiers (corresponding to four levels 364, 366, 372, and 374). Each tier of memory cells 202 can have a respective control gate (e.g., a respective word line) associated with memory cells 202 of the respective tier. The control gate in a tier is formed by a respective level of conductive material among conductive materials 340₀-340_{M}. In the example of FIG. 6, there are four tiers of control gates (associated with signals WL₀, WL₁, WL_{M-1}, and WL_{M}) on respective levels 364, 366, 372, and 374 for four respective tiers of memory cells 202 on levels 364, 366, 372, and 374. FIG. 6 shows a few tiers (e.g., four tiers) of memory device 200 for simplicity. However, memory device 200 can include up to (or more than) one hundred tiers.

Each of the blocks (e.g., blocks 290 through and 297 in FIG. 3A) of memory device 200 can also have their own tiers of memory cells 202 and respective control gates (e.g., respective word lines) for the memory cells. Each of the blocks (e.g., blocks 290 through and 297 in FIG. 3A) of memory device 200 can also have respective staircase structures similar to staircase structures 331 and 334 in block 291 in FIG. 6.

As shown in FIG. 6, memory device 200 can include materials 396 and 397 located over (e.g., formed over) substrate 399. Substrate 399 can also include circuitry 395 located under other components (e.g., memory cells 202) that are formed over substrate 399. Circuitry 395 can include circuit elements (e.g., transistors Tr1 and Tr2 shown in FIG. 6) coupled to circuit elements formed in memory device 200 and outside substrate 399. The circuit elements that are formed outside (e.g., formed over) substrate 399 can include data lines 270₀ through 270_{N} (shown in FIG. 3A) conductive contacts 365_{SGS}, 365₀-365_{M}, 365_{SGD0} through 365_{SGDi} (FIG. 3B), part of conductive paths 348 and other (not shown) conductive connections, and other circuit elements of memory device 200. Circuitry 395 can include numerous transistors. FIG. 6 symbolically shows such transistors as transistors Tr1 and Tr2 for simplicity. The circuit elements (e.g., transistors Tr1 and Tr2 and other elements) of circuitry 395 can be configured to perform part of a function of memory device 200. For example, transistors Tr1 and Tr2 can form or can be part of decoder circuits, driver circuits (e.g., drivers 140 in FIG. 1), buffers, sense amplifiers, charge pumps, and other circuitry of memory device 200.

As shown in FIG. 6, conductive paths (e.g., conductive routings) 348 of memory device 200 can include portions extending in the Z-direction (e.g., extending vertically). Some of such portions (e.g., vertical portions) can extend in the Z-direction through the tiers of memory device 200. Conductive paths 348 can include (e.g., can be coupled to) some of the conductive contacts (e.g., conductive contacts 365_{SGS}, 365₁-365_{M}, 365_{SGD0}-365_{SGDi}, and contact structures 344) or all of the conductive contacts of memory device 200. As shown in FIG. 6, conductive paths 348 can be coupled to circuitry 395. For example, at least one of conductive paths 348 can be coupled to at least one of transistors Tr1 and Tr2 of circuitry 395.

Conductive paths 348 can provide electrical connections between elements of memory device 200. For example, conductive paths 348 can be coupled to conductive contacts 365_{SGS}, 365₀-365_{M-1}, and 365_{SGD0}-365_{SGDi}, contact structures 344, and circuit elements (e.g., word line drivers and word line decoders, SGD and SGS drivers, and charge pumps, not shown) of circuitry 395 to provide electrical connections (e.g., in the form of signals WL₀ through WL_{M}, and SGD₀ through SGDᵢ, and SGS) from such circuit elements in circuitry 395 to respective conductive contacts 365₀-365_{M}, 365_{SGD0}-365_{SGDi}, and 365_{SGS}.

As shown in FIG. 6, conductive contacts 365_{SGS} and 365₀-365_{M} can include pillars (e.g., conductive pillars) that can have different lengths extending in the Z-direction (e.g., extending vertically (e.g., outward) from substrate 399). As shown in FIG. 6, the Z-direction is parallel to a direction from one tier to the next tier among the tiers of memory device 200. For simplicity, FIG. 6 shows a label for pillar 365P for only one of conductive contacts 365₀-365_{M}. A portion of conductive contact 365₁ labeled “FIG. 8” is described in detail below with reference to FIG. 8.

In FIG. 6, each of conductive contacts 365_{SGS} and 365₀-365_{M} (including a respective pillar) can include a conductive material that contacts (e.g., lands on) a respective level of a particular conductive material (among conductive materials 340_{SGS} and 340₀-340_{M}) at the location of a respective staircase structure (e.g., staircase structure 331 or 334). Each conductive contact 365_{SGS} and 365₀-365_{M} can form an electrical contact with a respective conductive material (among conductive materials 340_{SGS} and 340₀-340_{M}). Thus, conductive contacts 365_{SGS}, 365₀-365_{M} (and 365_{SGD0}-365_{SGDi} shown in FIG. 3B) can be part of conductive paths (e.g., part of conductive paths 348) to carry electrical signals to the select gate (e.g., source select gate associated with signal SGS), the control gates (e.g., control gates associated with signals WL_{M} and WL_{M-1}) and other select gates (e.g., drain select gates associated with signals SGD₀-SGDᵢ), respectively.

As shown in FIG. 6, conductive contact 365_{SGS} is electrically in contact with conductive materials 340_{SGS} and electrically separated from the rest of conductive materials (e.g., conductive materials 340₀-340_{M} and 340_{SGD0}-340_{SGDi}). Conductive contact 365₀ is electrically in contact with conductive materials 340₀ and electrically separated from the rest of conductive materials (e.g., conductive materials 340_{SGS}, 340₁, 340_{M-1}, 340_{M}, and 340_{SGDi}). Conductive contact 3651 is electrically in contact with conductive materials 340₁ and electrically separated from the rest of conductive materials (e.g., conductive materials 340_{SGS}, 340₀, 340_{M-1}, 340_{M}, and 340_{SGDi}). Thus, a conductive contact (e.g., conductive contact 365₀) can be electrically in contact with only one of the conductive materials among the conductive materials (e.g., conductive materials 340_{SGS}, 340₀-340_{M}, and 340_{SGD0}-340_{SGDi} in FIG. 6) of memory device 200.

Materials 396 and 397 shown in FIG. 6 can be part of source (e.g., source structure or source region) 298 shown in FIG. 2. Materials 396 and 397 can include different conductive materials. An example of material 396 includes tungsten silicide (or other conductive materials). An example of material 397 includes polysilicon. Materials 396 and 397 can include other conductive materials. Material 397 can include a single level (e.g., a single layer) of material in the Z-direction. For example, material 397 can include a single level (e.g., a single layer) of polysilicon. Alternatively, material 397 can include multiple levels (e.g., layers) of materials in the Z-direction. For example, material 397 can include levels (e.g., layers) of polysilicon interleaved with levels (e.g., layers) of oxide (e.g., silicon dioxide). Materials 396 and 397 can be part of electrical connections (e.g., lateral connections (e.g., a conductive plate) in the X-direction or the Y-direction) between elements of memory device 200 in circuitry 395. As shown in FIG. 6, materials 396 and 397 can form an electrical contact with pillars (memory cell pillars) 330 of memory cell strings 230.

As shown in FIG. 6, each pillar (memory cell pillar) 330 can include a structure 335 extending along the length (in the Z-direction) of pillar 330 and coupled to a respective data line (e.g., data line 270_{N-1} or 270_{N}) and the source (which includes materials 396 and 397) of memory device 200. Structure 335 can include a conductive channel portion that can be part of a conductive path between a respective data line (e.g., data line 270_{N}) and the source (e.g., includes materials 396 and 397) to carry current (e.g., current between data line 270_{N} and materials 396 and 397) during an operation (e.g., read, write, or erase) of memory device 200.

Structure 335 of pillar 330 can include multiple layers of different materials that can be part of a TANOS (TaN, Al₂O₃, Si₃N₄, SiO₂, Si) structure of pillar 330 or a structure similar to a TANOS structure. For example, structure 335 can include a dielectric portion (e.g., interpoly dielectric portion). The dielectric portion can include a charge blocking material or materials (e.g., a dielectric material including TaN and Al₂O₃) that can block a tunneling of a charge. Structure (e.g., TANOS structure) 335 can include a charge storage portion. The charge storage portion can include a charge storage element (e.g., charge storage material or materials, e.g., Si₃N₄) that can provide a charge storage function (e.g., trap charge) to represent a value of information stored in a respective memory cell 202. Structure (e.g., TANOS structure) 335 can include another dielectric portion (where the charge storage portion can be between the dielectric portions) that can include a tunnel dielectric material or materials (e.g., SiO₂). The tunnel dielectric material (or materials) can allow tunneling of a charge (e.g., electrons). In an alternative structure of memory device 200, structure 335 of pillar 330 can include or can be part be part of a SONOS (Si, SiO₂, Si₃N₄, SiO₂, Si) structure. In another alternative structure of memory device 200, structure 335 of pillar 330 can include or can be part of a floating gate structure. For example, structure 335 can include a charge storage portion that can include polysilicon (or other material) that can be part of a floating gate of a respective memory cell 202.

As shown in FIG. 6, contact structures 344 can include respective pillars 344P that have lengths extending in the Z-direction (e.g., extending vertically (e.g., outward) from substrate 399) that is also a direction from one tier to the next tier among the tiers of memory device 200. Contact structures 344 (including pillars 344P) can have the same length. Contact structures 344 can go through a respective portion of (e.g., go through respective holes in the tiers of) conductive materials 340_{SGS} and 340₀-340_{M} and dielectric materials 341. Thus, pillars 344P of contact structures 344 can be formed in holes in the tiers of memory device 200. Contact structures 344 are electrically separated from (not electrically coupled to) conductive materials 340_{SGS} and 340₀-340_{M}. Detailed description of contact structures 344 is included below with reference to FIG. 9 and FIG. 10.

As shown in FIG. 6, memory device 200 can include conductive islands 345 formed under (formed below in the Z-direction) and electrically coupled to respective contact structures 344. Conductive islands 345 can be electrically separated (e.g., laterally separated) from each other by a dielectric material 398. Conductive islands 345 can be coupled to respective pillars 344P of contact structures 344. Conductive islands 345 can also be coupled to respective conductive portions 346. Conductive portions 346 can be coupled to other elements (e.g., transistors Tr1 and Tr2) of circuitry 395. Thus, contact structures 344 can form electrical connections with circuitry 395 through respective pillars 344P, conductive islands 345, and conductive portions 346. Conductive islands 345 can be part of source 298 (which includes materials 396 and 397). For example, each conductive island 345 can include a separate portion of source 298. Thus, each conductive island 345 include a portion of materials 396 and 397.

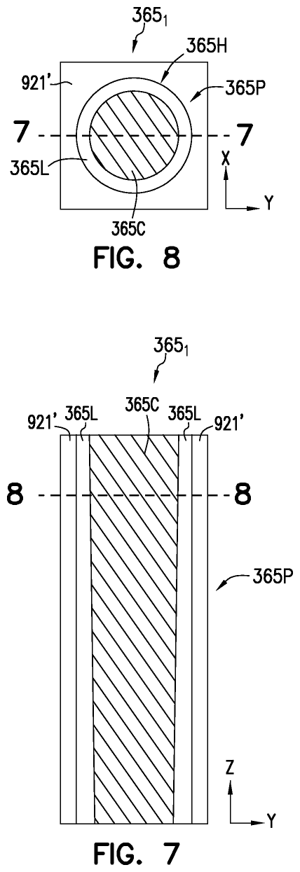

FIG. 7 shows detail of a portion (e.g., a side view (a cross-section)) of a conductive contact 365₁ including pillar 365P. FIG. 8 shows a top view (e.g., a cross-section parallel to the X-Y plane) along line 8 of FIG. 7. The following description refers to FIG. 7 and FIG. 8. As shown in FIG. 7, pillar 365P can include a dielectric liner portion 365L and a core portion (conductive core portion) 365C. Core portion 365C is adjacent dielectric liner portion 365L (e.g., interfaces with an inner surface of dielectric liner portion 365L). As shown in FIG. 8, core portion 365C can be surrounded by dielectric liner portion 365L with respect to the top view (e.g., X-Y plane view). With respect to the view (e.g., side view) shown in FIG. 7, at least a portion (e.g., left and right portions) of core portion 365C can be surrounded (e.g., surrounded on the left and right sides) by dielectric liner portion 365L. Dielectric liner portion 365L can include an oxide material (e.g., silicon dioxide). Core portion 365C is a conductive structure that includes a conductive material. The conductive material can include metal (e.g., tungsten), an alloy, or combination (e.g., different layers) of metal and alloy. As shown in FIG. 8, core portion 365C and dielectric liner portion 365L can be formed in an opening (e.g., a hole) 365H. Opening 365H can be formed in a dielectric material (e.g., silicon dioxide) 921′ (FIG. 7 and FIG. 8). Dielectric material 921′ can be part of dielectric material 921 (e.g., FIG. 9) that is formed during the process of forming contact structures 344.

FIG. 9 shows a portion (e.g., side view in the X-Z direction) of memory device 200 along line 9 in FIG. 3A, FIG. 4, and FIG. 5. Staircase structure 334 (in the X-Z direction) in FIG. 9 is the same as staircase structure 334 shown in a top view (in the X-Y direction) in FIG. 3B, FIG. 4, and FIG. 5. A side view (in the Y-Z direction) of staircase structure 334 is shown in FIG. 6. In FIG. 9, a portion (e.g., with respect to a top view) of memory device 200 along line 10-10 is shown in FIG. 10. The following description refers to FIG. 9 and FIG. 10.

In FIG. 9, conductive materials (levels of conductive material in different tiers) 340 can be part of (e.g., can correspond to) some or all of the conductive materials (e.g., conductive materials 340_{SGS} and 340₀ through 340_{M} in FIG. 6) of memory device 200. Thus, conductive materials 340 in FIG. 9 can form part of the control gates (e.g., the control gates associated with signals WL₀ through WL_{M} shown in the Y-Z direction in FIG. 6) of memory device 200.

As shown in FIG. 9 and FIG. 10, each of dielectric structures 351A and 351B can include a material (e.g., a liner) 951′ and a material 951″ (which can be another dielectric material or other non-conductive materials). For example, materials 951′ and 951″ can include any combination of silicon dioxide, silicon nitride, or other materials.

As shown in FIG. 9 and FIG. 10, each contact structure 344 can include a dielectric liner 344L and a conductive core 344C adjacent dielectric liner 344L. As shown in FIG. 10, conductive core 344C can be surrounded by dielectric liner 344L with respect to the top view (e.g., X-Y plane view). With respect to the view (e.g., side view) shown in FIG. 9, at least a portion (e.g., left and right portions) of conductive core 344C can be surrounded (e.g., surrounded on the left and right sides) by dielectric liner 344L. Dielectric liner 344L can include an oxide material (e.g., silicon dioxide). Conductive core 344C is a conductive structure that includes a conductive material.

in FIG. 9 and FIG. 10, dielectric liner 344L can include a dielectric material. In an example, dielectric material of dielectric liner 344L can include silicon dioxide (e.g., a single layer of silicon dioxide). In another example, dielectric material of dielectric liner 344L can include multiple layers of different dielectric materials (e.g., a silicon dioxide layer and another layer of dielectric material different from silicon dioxide). Conductive core 344C can include a conductive material (or materials). The conductive material can include metal (e.g., a single metal material (e.g., tungsten or other metals)), an alloy, a combination (e.g., different layers) of metal and alloy, or other conductive materials.

As shown in FIG. 9, contact structures 344 can be formed (e.g., vertically formed) at different locations at staircase structure 334. For example, two of contact structures 344 (e.g., outer (or left and right) contact structures) can be formed at respective sidewalls SW1 and SW2. One of contact structures 344 can be formed between (e.g., in the middle) of the two outer contact structures. As shown in FIG. 9 and FIG. 10, staircase structure 334 can include a dielectric material 921 formed in a region between sidewalls SW1 and SW2 of staircase structure 334. Each contact structure 344 can be formed in an opening (e.g., hole) in dielectric material 921. As shown in FIG. 9, some of contact structures 344 (e.g., two outer contact structures 344) can also be formed through part of respective sidewalls SW1 and SW2 of staircase structure 334.

FIG. 11A shows a side view (e.g., cross-section) of memory device 200 of FIG. 3A along line 11A. Dielectric materials 921 and 921″ are the same as those shown in FIG. 3B, FIG. 3C, and FIG. 3D.

As shown in FIG. 11A, width W1 can correspond to a distance (e.g., in nanometer unit) measured at reference level, such as a level 342, between sidewalls S1 and S2 of trench structure 381. FIG. 11A also shows a distance 1191 at region 391. Distance 1191 can be measured at level 342 between sidewall S2 of trench structure 381 and sidewall SW1 of staircase structure 334. The distance corresponding to width W1 can be greater than distance 1191.

As shown in FIG. 11A, memory device 200 can include contact structures 344D formed in trench structures 381 and 382. Contact structures 344D can be similar to contact structures 344 and may be formed concurrently with contact structures 344. However, contact structures 344D may not be electrically coupled to other elements (e.g., may not be coupled to conductive islands 345 and circuitry 395 (FIG. 6)) of memory device 200. Thus, contact structures 344D may be called dummy contact structures. In an alternative structure of memory device 200, some or all of contact structures 344D may not be formed in memory device 200.

FIG. 11B shows a side view (e.g., cross-section) of memory device 200 of FIG. 3A along line 11B. The portion of memory device 200 in FIG. 11B can be similar to that of the portion of memory device 200. For example, trench structures 383 and 384 can have respective widths W1′ and W2′ that can be similar to widths W1 and W2, respectively. Distance 1191′ at region 393 can be similar to distance 1191 in FIG. 11A. The distance corresponding to width W1′ can be greater than distance 1191′.

As shown in FIG. 11B, memory device 200 can include contact structures 344D formed in trench structures 383 and 384. Contact structures 344D can be similar to contact structures 344 and may be formed concurrently with contact structures 344. However, contact structures 344D may not be electrically coupled to other elements (e.g., may not be coupled to conductive islands 345 and circuitry 395 (FIG. 6)) of memory device 200. Thus, contact structures 344D may be called dummy contact structures. In an alternative structure of memory device 200, some or all of contact structures 344D may not be formed in memory device 200. In another alterative structure of memory device 200, some or all of contact structures 344D may not be dummy contact structures but may be like contact structures 344 that electrically couple to circuitry 395 (FIG. 6) of memory device 200.

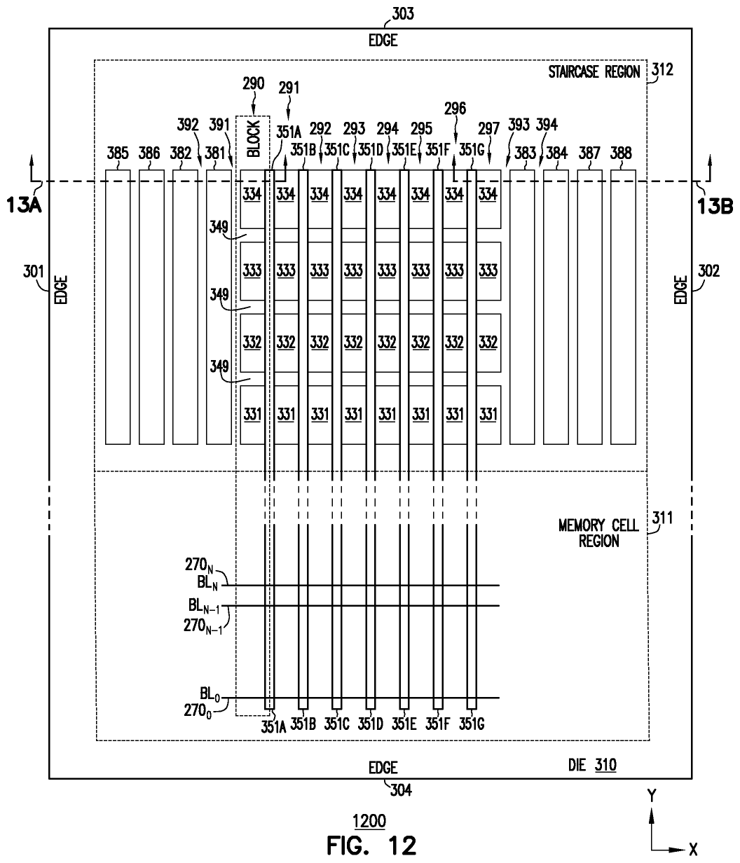

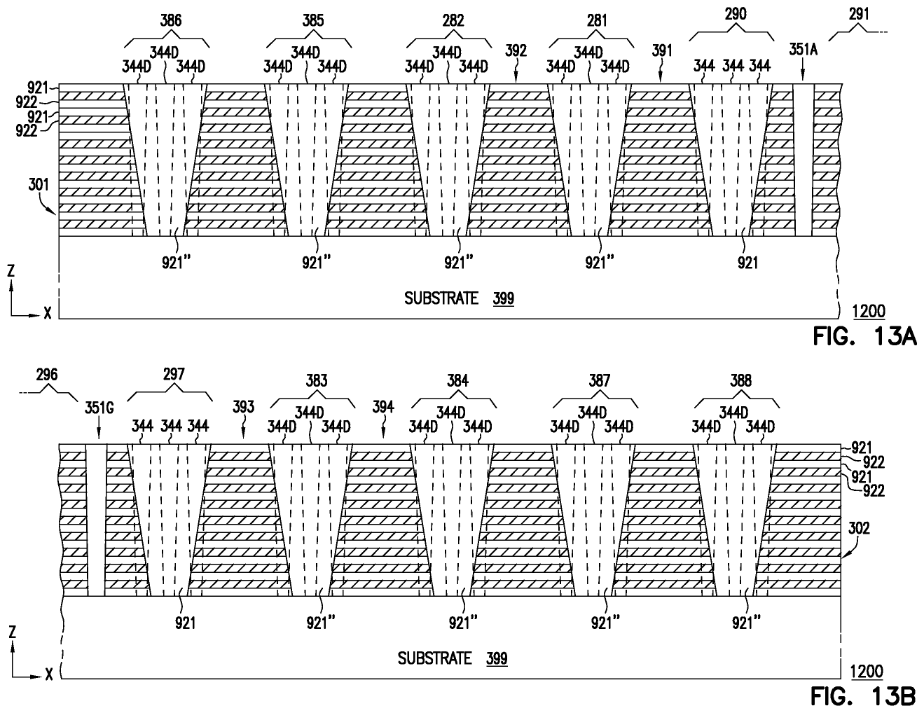

FIG. 12 shows a memory device 1200 including four trench structures 381, 382, 385, and 386 between edge 301 and block 290 and four trench structures 383, 384, 387, and 388 between block 297 and edge 302. Memory device 1200 can be a variation of memory device 200 of FIG. 3A. Thus, device 1200 can include elements similar to those of memory device 200. Differences between memory devices 200 and 1200 include the number of trench structures between edge 301 and block 290 and trench structures between edge 302 and block 297. In FIG. 12, a portion (e.g., side view in the X-Z direction) of memory device 1200 along lines 13A and 13B are shown in FIG. 13A and FIG. 13B, respectively.

FIG. 13A shows a portion of memory device 1200 that is similar to the portion of memory device 200 of FIG. 11A except for the addition of trench structures 385 and 386 on the side (e.g., left side) of memory device 1200 at edge 301. FIG. 13B shows a portion of memory device 1200 that is similar to the portion of memory device 200 of FIG. 11B except for the addition of trench structures 387 and 388 on the side (e.g., right side) of memory device 1200 at edge 302.

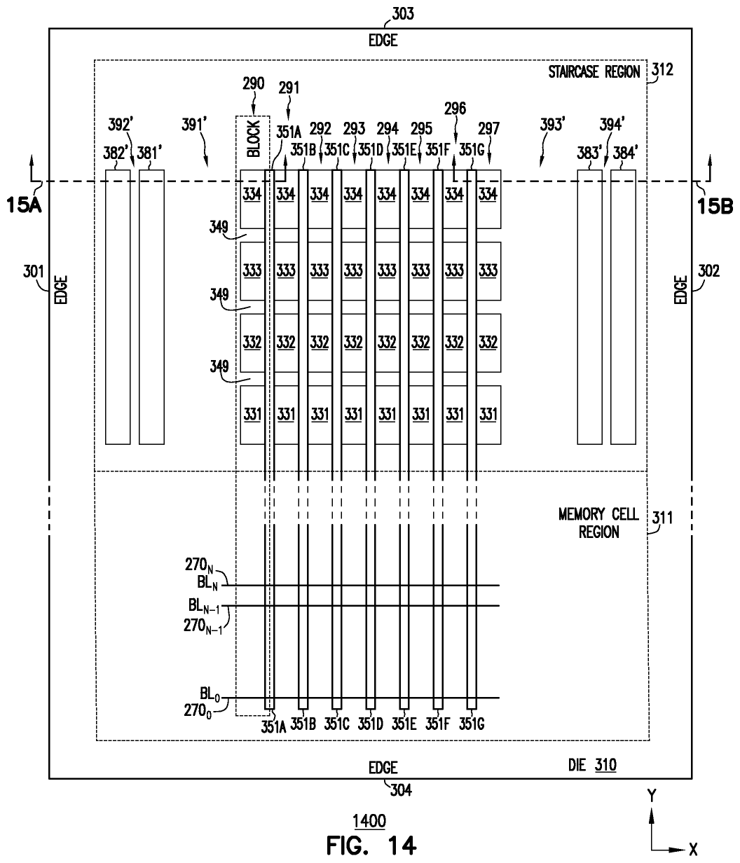

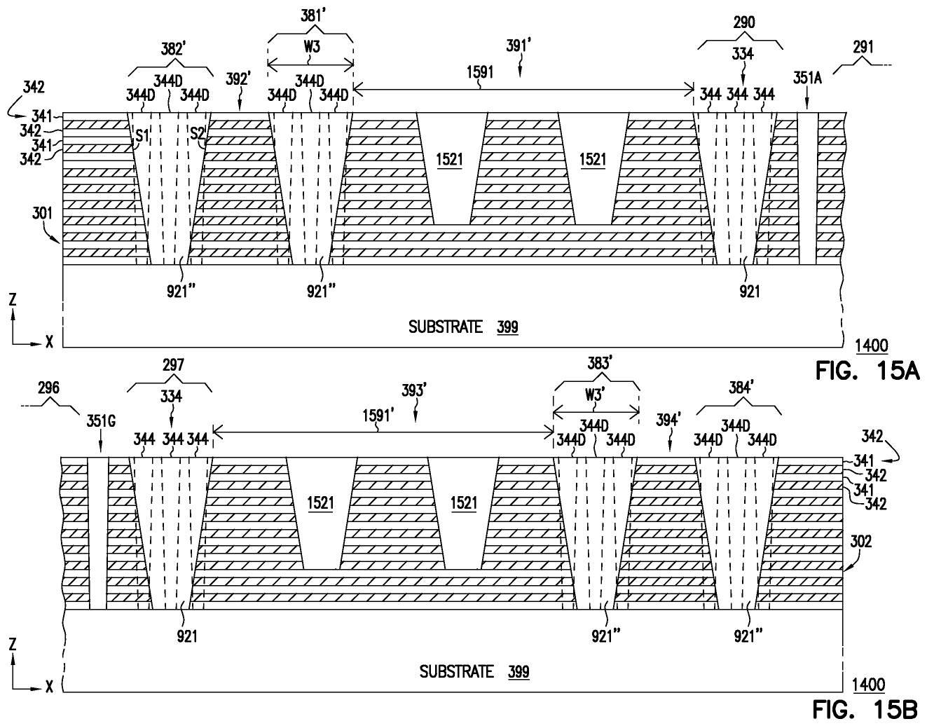

FIG. 14 shows a memory device 1400 including trench structures 381′, 382′, 383′, and 384′ and regions 391′ and 393′ between trench structures 381′ and 383′ and respective staircase structures in blocks 290 and 297. Memory device 1400 can be a variation of memory device 200 of FIG. 3A. Thus, device 1400 can include elements similar to those of memory device 200. Trench structures 381′, 382′, 383′, and 384′ in FIG. 14 are similar to trenches structures 381, 382, 383, and 384, respectively. Regions 391′, 392′, 393′, and 394′ in FIG. 14 are similar to regions 391, 392, 393, and 394 in FIG. 3A. However, the dimensions (e.g., widths) of regions 391′ and 393′ in the in FIG. 14 are greater than the dimensions (e.g., widths) of regions 391 and 393, respectively. In FIG. 14, a portion (e.g., side view in the X-Z direction) of memory device 1400 along lines 15A and 15B is shown in FIG. 15A and FIG. 15B, respectively.

FIG. 15A shows a portion of memory device 1400 that is similar to the portion of memory device 200 of FIG. 11A except that distance (e.g., width) 1591 in FIG. 15A is greater than distance 1191 in FIG. 11A and distance (e.g., width) 1591′ in FIG. 15B is greater than distance 1191′ in FIG. 11B.

Further, as shown in FIG. 15A, memory device 1400 can include dielectric structures 1521 between staircase structure 334 and trench structure 381′. Each of dielectric structures 1521 can include a trench (not labeled) and a dielectric material formed in the tiers of memory device 200. Dielectric structures 1521 are dummy dielectric structures and the trenches of dielectric structures 1521 may be formed when the trenches for other trench structures (e.g., trench of staircase structure 333 in FIG. 3C) are formed. As shown in FIG. 15A, the trench of dielectric structures 1521 can have a depth (in the Z-direction) less than the depth (e.g., depth W4) of trench structure 381′. The depth of trench of dielectric structures 1521 can be similar to (or the same as) the depth of the trench of staircase structure 333 (FIG. 3C).

In FIG. 15A, width W3 of structure 381′ can be similar to (or the same as) width W1 of structure 381. Width W3 can correspond to a distance (e.g., in nanometer unit) measured at reference level, such as a level 342, between sidewalls S1 and S2 of trench structure 381′. Distance 1591 at region 391′ can be measured at level 342 between sidewall S2 of trench structure 381′ and sidewall SW1 of staircase structure 334. The distance corresponding to width W3 can be less than distance 1591. In some examples, the distance corresponding to width W3 can be less than one-half of distance 1591.

In FIG. 15B, trench structures 383′ can have a width W3′ that can be similar to width W3 of trench structure 383 of FIG. 11B. Distance 1591′ at region 393′ can be similar to distance 1591 in FIG. 15A. The distance corresponding to width W3′ can be less than distance 1591′. In some examples, the distance corresponding to width W3′ can be less than one-half of distance 1591′.

Further, as shown in FIG. 15A and FIG. 15B, memory device 1400 can include two dielectric structures 1521 between staircase structure 334 of block 290 and trench structure 383′ (FIG. 15A), and two dielectric structures 1521 between staircase structure 334 of block 297 and trench structure 383′ (FIG. 15B). Each of dielectric structures 1521 can include a trench (not labeled) and a dielectric material formed in the tiers of memory device 200. Dielectric structures 1521 are dummy dielectric structures and the trenches of dielectric structures 1521 may be formed when the trenches for other trench structures (e.g., trench of staircase structure 333 in FIG. 3C) are formed. As shown in FIG. 15A and FIG. 15B, the trench of dielectric structures 1521 can have a depth (in the Z-direction) less than the depth (e.g., depth W4) of trench structure 381′ or trench structure 383′. The depth of trench of dielectric structures 1521 can be similar to (or the same as) the depth of the trench of staircase structure 333 (FIG. 3C). In an alternative structure, memory device 1400 can include fewer or more than two dielectric structure 1521 between staircase structure 334 of block 290 and trench structure 381′ (FIG. 15A) and between staircase structure 334 of block 297 and trench structure 383′ (FIG. 15B).

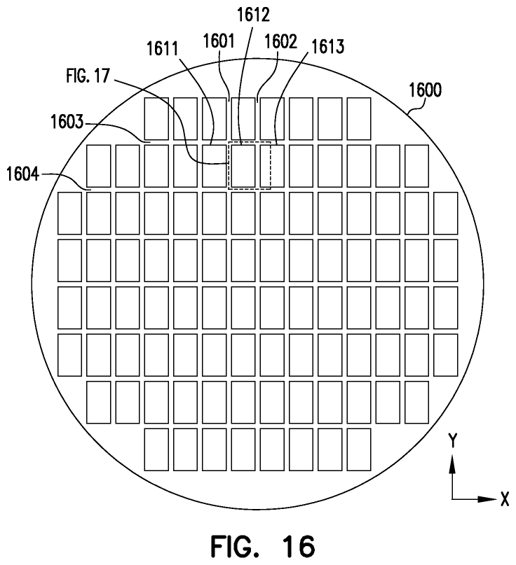

FIG. 16 shows a wafer (e.g., a semiconductor wafer) 1600 including die portions 1611, 1612, and 1613 and scribe line regions 1601 and 1602, according to some embodiments described herein. Wafer 1600 can include elements (e.g., memory cells and associated circuitry) formed within each of die portions 1611, 1612, and 1613. As shown in FIG. 16, wafer 1600 includes numerous die portions like die portions 1611, 1612, and 1613. For simplicity, only three die portions (e.g., die portions 1611, 1612, and 1613) are labeled in FIG. 16.

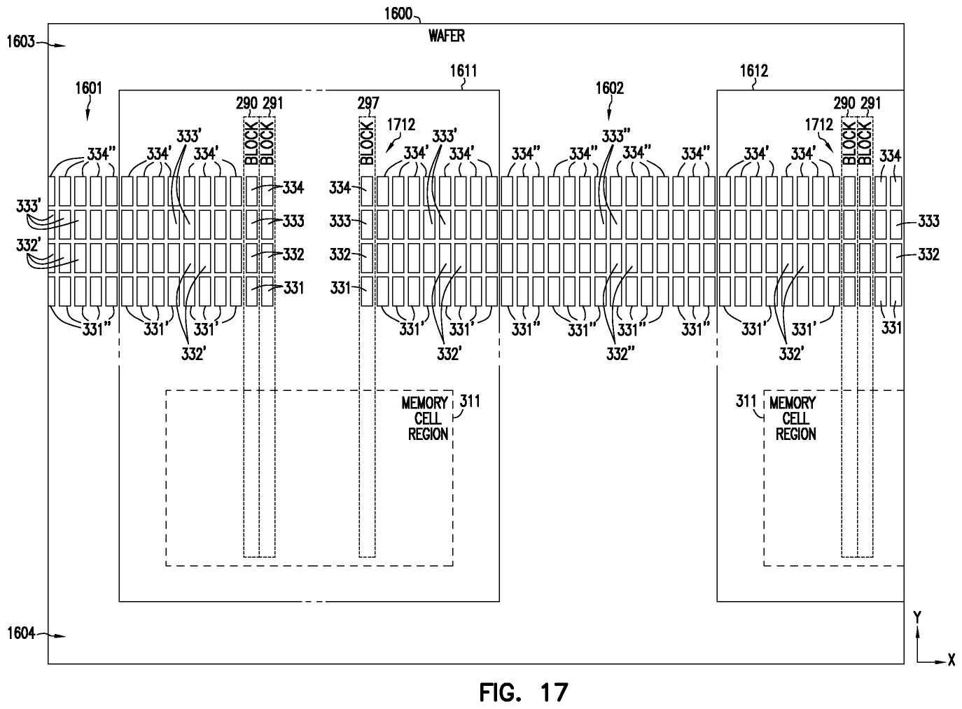

As shown in FIG. 16, wafer 1600 can include numerous scribe line regions like scribe line regions 1601 and 1602 in the Y-direction, and numerous scribe line regions like scribe line regions 1603 and 1604 in the X-direction. For simplicity, only four scribe line regions (e.g., scribe line regions 1601, 1602, 1603, and 1604) are labeled in FIG. 16. After circuit elements (e.g., circuit elements for memory devices) are formed in the die portions (e.g., die portions 1611, 1612, and 1613), wafer 1600 can be cut along the scribe line regions (e.g., scribe line regions 1601, 1602, 1603, and 1604) to divide wafer 1600 into separate dies. Each separated die can include elements (e.g., memory cells and associated circuitry) in a respective die portion (e.g., die portion 1611). A portion of wafer 1600 labeled “FIG. 17” is shown in FIG. 17.

As shown in FIG. 17, in each of die portions 1611 and 1612, wafer 1600 can include memory cell region 311 (like memory cell region 311 of memory device 200 in FIG. 3A) and a staircase region 1712 adjacent memory cell region 311 in the Y-direction. Staircase region 1712 can include staircase structures 331, 332, 333, and 334 like those of memory device 200 in FIG. 3A. As shown in FIG. 17, each of die portions 1611 and 1612 can include blocks 290 through 297 like blocks 290 through 297 of memory device 200 of FIG. 3A.

As shown in FIG. 17, wafer 1600 also include trench structures 331′, 332′, 333′, and 334′ adjacent (in the X-direction) staircase structures 331, 332, 333, and 334, respectively, in staircase region 1712 of respective die portions 1611 and 1612. Wafer 1600 also includes trench structures 331″, 332″, 333″, and 334″ in scribe line regions 1601 and 1602.

Trench structures 331′, 332′, 333′, and 334′ can be similar to or the same as staircase structures 331, 332, 333, and 334, respectively. Trench structures 331″, 332″, 333″, and 334″ can be similar to or the same as staircase structures 331, 332, 333, and 334, respectively.

As shown in FIG. 17, trench structures 331′ and 331″ can have the same length (in the Y-direction) as staircase structures 331. Trench structures 331′ and 331″ and staircase structures 331 can be adjacent each other and can be arranged (can be formed) in a row (e.g., a continuous row of similar trenches) in the X-direction between staircase regions 1712 of die portions 1611 and 1612 including scribe line region 1602 between staircase regions 1712 of die portions 1611 and 1612.

Trench structures 332′ and 332″ can have the same length (in the Y-direction) as staircase structures 332. Trench structures 332′ and 332″ and staircase structures 332 can be adjacent each other and can be arranged (can be formed) in a row (e.g., a continuous row of similar trenches) in the X-direction between staircase regions 1712 of die portions 1611 and 1612 including scribe line region 1602 between staircase regions 1712 of die portions 1611 and 1612.

Trench structures 333′ and 333″ can have the same length (in the Y-direction) as staircase structures 333. Trench structures 333′ and 333″ and staircase structures 333 can be adjacent each other and can be arranged (can be formed) in a row (e.g., a continuous row of similar trenches) in the X-direction between staircase regions 1712 of die portions 1611 and 1612 including scribe line region 1602 between staircase regions 1712 of die portions 1611 and 1612.

Trench structures 334′ and 334″ can have the same length (in the Y-direction) as staircase structures 334. Trench structures 334′ and 334″ and staircase structures 334 can be adjacent each other and can be arranged (can be formed) in a row (e.g., a continuous row of similar trenches) in the X-direction between staircase regions 1712 of die portions 1611 and 1612 including scribe line region 1602 between staircase regions 1712 of die portions 1611 and 1612.

As described in more detail below, trench structures 331′, 332′, 333′, and 334′ and trench structures 331″, 332″, 333″, and 334″ can be called dummy structures or dummy staircase structures that are formed to improve the structures of staircase structures 331, 332, 333, and 334, respectively.

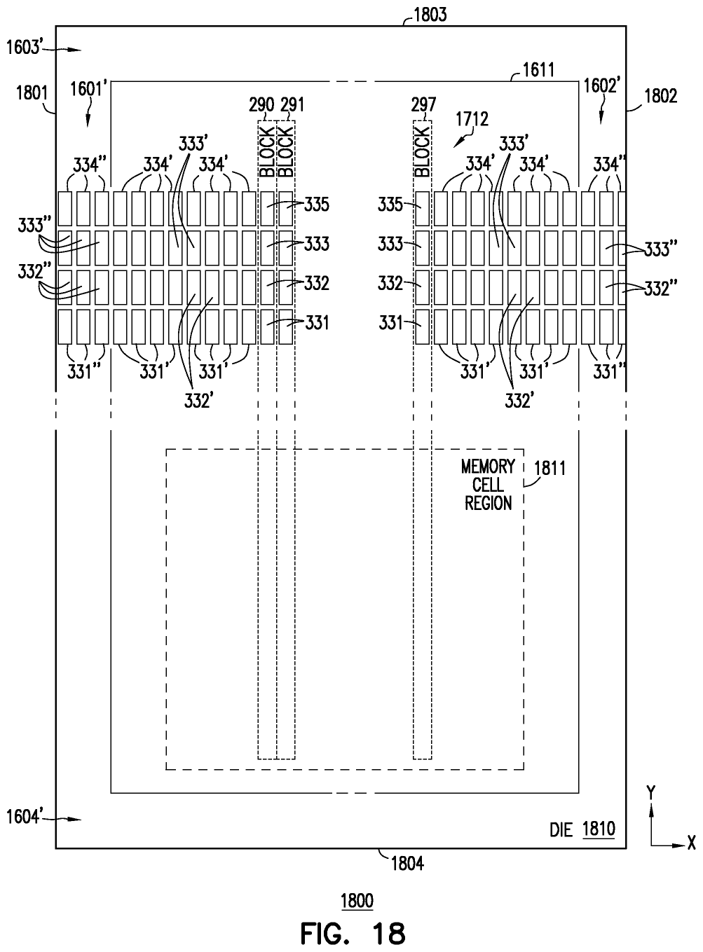

FIG. 18 shows a memory device 1800 that includes a die 1810 having trench structures in scribe line regions 1601′ and 1602′, according to some embodiments described herein. Die 1810 can include die portion 1611 that was separated (e.g., cut) from wafer 1600 (FIG. 16 and FIG. 17). As shown in FIG. 18, die 1810 can include edges 1801 and 1802 opposite from each other in the X-directions, and edges 1803 and 1804 opposite from each other in the Y-direction.

Scribe line regions 1601′ and 1602′ are along edges 1801 and 1802, respectively. Die 1810 can also include scribe line regions 1603′ and 1604′ along edges 1803 and 1804, respectively. Scribe line regions 1601′, 1602′, 1603′, and 1604′ can include respective remaining portions (e.g., partial portions) of scribe line regions 1601, 1602, 1603, and 1604 in FIG. 16 and FIG. 17. Thus, scribe line regions 1601′, 1602′, 1603′, and 1604′ of memory device 1800 in FIG. 18 are part of respective scribe line regions 1601, 1602, 1603, and 1604 that were bordering die portion 1612 (FIG. 16 and FIG. 17) before die portion 1611 is separated (e.g., cut) from wafer 1600 (FIG. 16 and FIG. 17).

As shown in FIG. 18, like die portion 1611 in FIG. 17, die 1810 in FIG. 18 can include staircase structures 331, 332, 333, and 334 and trench structures 331′, 332′, 333′, and 334′ in staircase region 1712.

In die 1810, trench structures 331″, 332″, 333″, and 334″ in scribe line region 1601′ and 1602′ are remaining portions of trench structures 331″, 332″, 333″, and 334″ in scribe line regions 1601 and 1602 in FIG. 17 after another portion of trench structures 331″, 332″, 333″, and 334″ in FIG. 17 was cut (e.g., cut when die portion 1612 was separated from other die portions of wafer 1600 in FIG. 16 and FIG. 17).

As shown in FIG. 18, the scribe line regions (e.g., scribe line region 1601′) of die portion 1611 may include only a portion of a trench structure (not the entire trench structure) of some of trench structures 331″, 332″, 333″, and 334″ (e.g., partial trench structures 331″, 332″, 333″, and 334″ at edge 1802). The partial trench structures can be the result of the process (e.g., cutting) that separates die portion of FIG. 18 from wafer 1600 of FIG. 17.

The following descriptions with reference to FIG. 19A through FIG. 21B describe some example processes of forming memory devices that can also be used to form the memory devices above (e.g., memory devices 200, 1200, 1400, and 1800). The processes of forming the memory devices described below include additional processes to complete the processes of forming the described memory device. However, for simplicity and not to obscure the described example processes, such additional processes to form a complete memory device are omitted from this description.

FIG. 19A and FIG. 19B show different views of a portion of a memory device 1900 during processes of forming part of staircase structures and trench structures of memory device 1900, according to some embodiments described herein. FIG. 19A shows a side view of a portion of a memory device 1900 along line 19A-19A of FIG. 19B. FIG. 19B shows a top view of memory device 1900 of FIG. 19A.

The processes associated with FIG. 19A and FIG. 19B can be used to form part of memory device 200 (FIG. 3A) and memory device 1200 (FIG. 12). For example, the processes associated with FIG. 19A and FIG. 19B can be used to form trenches of staircase structures 334 (FIG. 3A) and trenches of trench structures 381, 382, 383, and 384 (FIG. 3A) of memory device 200. Thus, staircase structures 334 (FIG. 3A) of memory device 200 can include respective trenches like trenches 344T of memory device 1900 in FIG. 19A and trench structures 381, 382, 383, and 384 (FIG. 3A) of memory device 200 can include trenches like trenches 381T, 382T, 383T, and 384T of memory device 1900 in FIG. 19A. In FIG. 19A, the locations and structures of blocks 290′ through 297′ can correspond to the locations and structures of blocks 290 through 297 of memory device 200 (FIG. 3A).

FIG. 19A and FIG. 19B show memory device 1900 after a photoresist 1915 is formed over the tiers of memory device 1900. The tiers can include levels of dielectric materials 341′ interleaved with levels of dielectric materials 1923. Dielectric materials 341′ and 1923 can be formed (e.g., stacked) one over another over a substrate 1999 before photoresist 1915 is formed. Substrate 1999 is similar to or the same as substrate 399 of memory device 200 (FIG. 6).

Dielectric materials 341′ in FIG. 19A can include silicon dioxide and can correspond to dielectric materials 341 in the tiers of memory device 200 in FIG. 11A and FIG. 11B. Dielectric materials 1923 in FIG. 19A can include silicon nitride.

FIG. 19A and FIG. 19B show after photoresist 1915 is patterned to include portions 1915L, 1915R, 1915P, openings 1934, 1981, 1982, 1983, and 1984. Portions 1915L and 1915R can be part of the bulk of photoresist 1915. Portions 1915P can have the same width in the X-direction. Each of portions 1915L and 1915R can have a width greater than the width of each of portions 1915P.

As shown in FIG. 19B, each of openings 1981, 1982, 1983, and 1984 can have a length extending (extend continuously) in the Y-direction. Each of openings 1934 can have a length in the Y-direction. As shown in FIG. 19B, the length of each of openings 1981, 1982, 1983, and 1984 is much greater than the length of each of openings 1934.

The processes associated with FIG. 19A and FIG. 19B also include removing (e.g., etching) portions of materials 341′ and 1923 at the locations of openings 1934, 1981, 1982, 1983, and 1984 to form trenches 344T, 381T, 382T, 383T, and 384T at respective locations of openings 1934, 1981, 1982, 1983, and 1984. Trenches 334T can be part of trenches included in respective staircase structures of blocks 290′ through 297′ of memory device 1900 that can be similar to or the same as staircase structures 334 of memory device 200 (FIG. 3A). Trenches 381T, 382T, 383T, and 384T can be part of trenches included in respective trench structures that can be similar to or the same as trench structures 381, 382, 383, and 384 of memory device 200 (FIG. 3A). The process of forming memory device 1900 can also include forming trenches (shown in dashed rectangles in FIG. 19A) for the staircase structures of memory device 1900 that are similar to staircase structures 332, 333, and 334 of memory device 200 (FIG. 3A). Photoresist 1915 is removed from memory device 1900 after trenches 344T, 381T, 382T, 383T, and 384T are formed.

After the processes of associated with FIG. 19A and FIG. 19B are performed (e.g., after trenches 344T, 381T, 382T, 383T, and 384T are formed), the processes of forming memory device 1900 can further include a process (e.g., a replacement process) of replacing the levels dielectric materials (e.g., silicon nitride) 1923 with respective levels of conductive materials (e.g., tungsten) like levels of conductive materials 340 in FIG. 3C. For example, such a process (e.g., a replacement process) can include removing (e.g., exhuming) dielectric materials 1923 (FIG. 19A) from tiers of memory device 1900, then forming (e.g., filling) respective level of conductive materials at the locations of dielectric materials 1923 that were removed. The levels of conductive materials (which replace dielectric materials 1923) can be part of control gates associated with the memory cells of memory device 1900 like conductive material 340₀-340_{M} of memory device 200 (FIG. 3C and FIG. 6).

FIG. 19A and FIG. 19B show an example where photoresist 1915 has two openings 1981 and 1982 adjacent portion (e.g., bulk portion) 1915L and two openings 1983 and 1984 adjacent portion (e.g., bulk portion) 1915R. However, in an alternative, process photoresist 1915 can have fewer than two openings or more than two openings adjacent portion 1915L, and fewer than two openings or more than two openings adjacent portion 1915R. For example, in an alternative process, photoresist 1915 can have four openings adjacent portion 1915L and four openings adjacent portion 1915R. Such alternative process can be used to form trenches of trench structure 381 through 384 of memory device 1200 (FIG. 12).

Forming memory device 1900 in the processes described above with reference to FIG. 19A and FIG. 19B provides improvements and benefits over an alternative process. For example, in an alternative process, photoresist 1915 (FIG. 19A and FIG. 19B) may be formed (e.g., patterned) such that openings 1981, 1982, 1983, and 1984 (FIG. 19B) can have the same length in the Y-direction as openings 1934 (FIG. 19B). As described above, openings 1934 in photoresist 1915 are used to form trenches 334T (FIG. 19A) for staircase structures like staircase structure 334 of memory device 200 (FIG. 2 through FIG. 11B). However, patterning openings 1981, 1982, 1983, and 1984 to be the same length as openings 1934 in an alternative process can cause of portions 1915P (FIG. 19A) near openings 1981, 1983, and 1984 to tilt (bend) from target positions. For example, in the alternative process, a few portions 1915P (FIG. 19A) near opening 1981 may tilt toward portion 1915L. A few portions 1915P (FIG. 19A) near opening 1983 may tilt toward portion 1915R. The reasons for the tilt (occurring in the alternative process) may include differences in degree of shrinkage among different portions of the photoresist 1915 during processing of the photoresist (e.g., during bake and/or develop steps).

The tilt of photoresist portions, in the alternative process mentioned above, can in turn lead to misalignment of some of dielectric structures near portions 1915L and 1915R, such as misalignment of at least dielectric structures (e.g., block dividers) like dielectric structures 351A and 351G in FIG. 3A, FIG. 11A, and FIG. 11B. A moderate misalignment of such dielectric structures can cause block bending where the structures of some of the blocks are bent (e.g., block bending in blocks 290 and 297 in FIG. 11A and FIG. 11B or blocks 290′ and 297′ in FIG. 19A). Block bending can impact the structures of elements in the blocks. Severe misalignment can lead to some of dielectric structures (e.g., like dielectric structures 351A and 351G in FIG. 3A, FIG. 11A, and FIG. 11B) to cut into some of staircase structures 331, 332, 333, and 334. This can cause defects in the memory device, leading to reduced yield.

The tilt of photoresist portions of photoresist 1915, in the alternative process mentioned above, can also lead to asymmetry in sidewalls (e.g., like sidewalls SW1 and SW2 in FIG. 11A and FIG. 11B) of some of the staircase structures. The asymmetry can cause contact structures (e.g., like contact structures 344 in FIG. 11A and FIG. 11B) to be formed at locations different from target locations at respective staircase structures.

In the processes described above with reference to FIG. 19A and FIG. 19B, photoresist 1915 is formed with lengths of openings 1981, 1982, 1983, and 1984 greater than the lengths of openings 1934. This can reduce or eliminate the tilt of photoresist portions near portions 1915L and 1915R. This in turn can reduce or eliminate misalignment and sidewall asymmetry discussed above. Therefore, the structures of the staircase structures (e.g., staircase structures 331, 332, 333, and 334 in FIG. 3A) of the memory device (e.g., memory device 200 in FIG. 3A or memory device 1900 in FIG. 19A) can be improved in comparison with the memory device formed by an alternative process. Yield may also be higher in comparison with that of the alterative processes.

As mentioned above, the processes of forming memory device 1900 described above with reference to FIG. 19A and FIG. 19B can also be used to form memory device 200 (FIG. 3A) and memory device 1200 (FIG. 12). Thus, memory device 200 and memory device 1200 can also have improvements and benefits like memory device 1900.

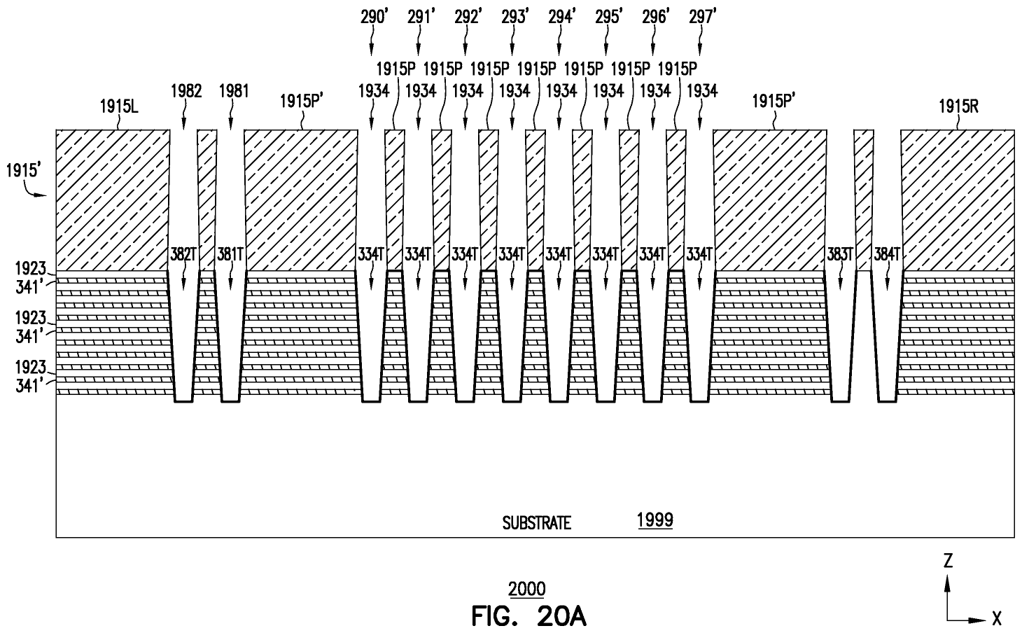

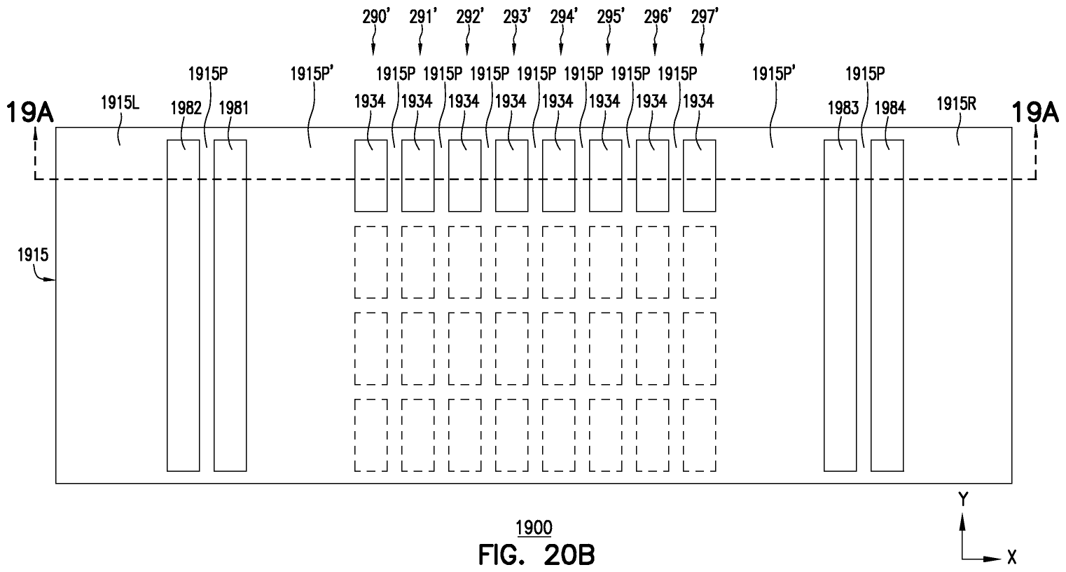

FIG. 20A and FIG. 20B show different views of a portion of a memory device 2000 during processes of forming part of staircase structures and trench structures, according to some embodiments described herein. FIG. 20A shows a side view of a portion of a memory device 2000 along line 20A-20A of FIG. 20B. FIG. 20B shows a top view of memory device 2000 of FIG. 20A.

The processes associated with FIG. 20A and FIG. 20B can also be used to form part of memory device 1400 (FIG. 14). For example, the processes associated with FIG. 20A and FIG. 20B can be used to form trenches of staircase structures 334 (FIG. 14) and trenches of trench structures 381′, 382′, 383′, and 384′ (FIG. 14) of memory device 1400. As shown in FIG. 20A, the locations and structures of blocks 290′ through 297′ can correspond to the locations and structures of blocks 290 through 297 of memory device 1400 (e.g., FIG. 14).

Memory device 2000 formed by the processes described with reference to FIG. 20A and FIG. 20B can have similar structure as memory device 1900 (FIG. 19A and FIG. 19B). Thus, similar or the same structures in memory devices 1900 and 2000 are given the same reference labels.

FIG. 20A and FIG. 20B show after a photoresist 1915′ is patterned. Photoresist 1915′ can be similar to photoresist 1915 (FIG. 19A and FIG. 19B). Thus, similar or the same portions of photoresists 1915 and 1915′ are given the same reference labels. Differences between forming photoresists 1915 and 1915′ include portions 1915P′ of photoresist 1915′.

As shown in FIG. 20A and FIG. 20B, photoresist 1915′ can include portions 1915P′ that have a dimension (e.g., a width) in the X-direction that is greater than the dimension (e.g., a width) in the X-direction of each of portions 1915P. Thus, the distance between trench 381T and an adjacent trench 344T (e.g., left-most trench 344T) in FIG. 20A is greater than the distance between trench 381T and an adjacent trench 344T (e.g., left-most trench 344T) in FIG. 19A. Similarly, the distance between trench 383T and an adjacent trench 344T (e.g., right-most trench 344T) in FIG. 20A is greater than the distance between trench 381T and an adjacent trench 344T (e.g., right-most trench 344T) in FIG. 19A.

Forming memory device 2000 in the processes described above with reference to FIG. 20A and FIG. 20B provide improvements and benefits like the processes of forming memory device 1900 (FIG. 19A and FIG. 19B). For example, the processes described above with reference to FIG. 20A and FIG. 20B can reduce or eliminate misalignment and sidewall asymmetry discussed above. This can lead to improved structures of the staircase structures of memory device 2000 (e.g., like staircase structures 331, 332, 333, and 334 in FIG. 3A) and a higher yield.

As mentioned above, the processes of forming memory device 2000 described above with reference to FIG. 20A and FIG. 20B can also be used to form memory device 1400 (FIG. 14). Thus, memory device 1400 can also have improvements and benefits like memory device 1900 and memory device 2000.

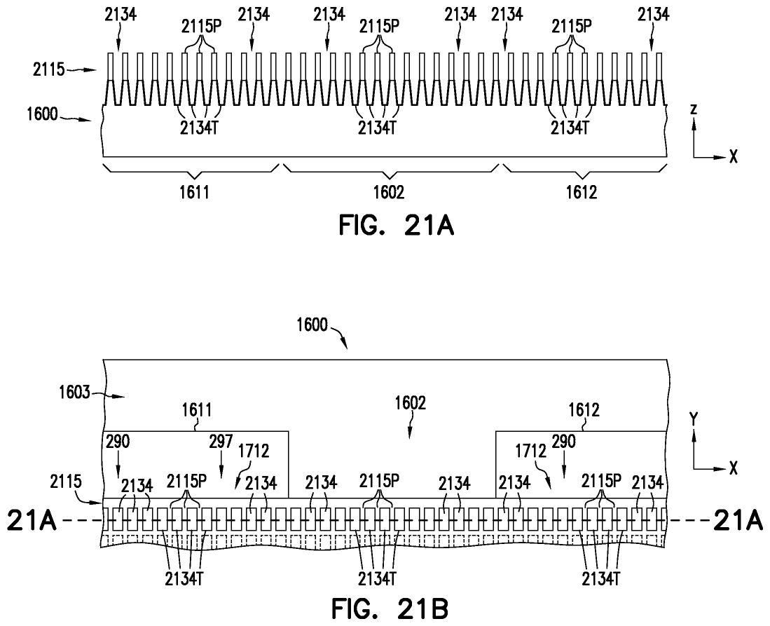

FIG. 21A and FIG. 21B show different views of a portion of wafer 1600 of FIG. 16 during processes of forming part of staircase structures and trench structures in wafer 1600 in FIG. 16 including forming memory device 1800 in FIG. 18, according to some embodiments described herein. FIG. 21A shows a side view of a portion of wafer 1600 along line 21A-21A of FIG. 21B. FIG. 21B shows a top view of the portion of wafer 1600 of FIG. 21A. The same elements between FIG. 16, FIG. 17, FIG. 21A, and FIG. 21B are given the same reference labels. For simplicity FIG. 21A and FIG. 21B do not show memory cell regions 1711 (adjacent staircase region 1712) in die portions 1611 and 1612, and only some of the blocks (e.g., blocks 290 and 297) in die portions 1611 and 1612 are labeled.

The processes associated with FIG. 21A and FIG. 21B can be used to form trenches of staircase structures 334 and trenches of trench structures 334′ and 334″ in respective die portions (e.g., die portions 1611 and 1612 in FIG. 17) and scribe line regions (e.g., scribe line region 1602 in FIG. 16 and FIG. 17) of wafer 1600.

FIG. 21A and FIG. 21B show wafer 1600 after a photoresist 2115 is formed and patterned to include portions 2115P and openings 2134 between portions 2115P. Portions 2115P can have the same width in the X-direction and same length in the Y-direction. Openings 2134 can have the same width in the X-direction and same length in the Y-direction. As shown in FIG. 21A and FIG. 21B, portions 2115P and openings 2134 are interleaved with each other, such that portions 2115P and openings 2134 can form a repeated pattern (e.g., a continuous pattern in a row) of portions 2115P and openings 2134 that extend over staircase regions the die portions (e.g., die portions 1611 and 1612) and the scribe line regions (e.g., scribe line region 1602) between the die portions.

As shown in FIG. 21A and FIG. 21B, based on the structure of photoresist 2115, a repeated pattern of trenches (e.g., a row of trenches) 2134T are formed in wafer 1600. Trenches 2134T in FIG. 21A and FIG. 21B correspond to a continuous row of trenches in wafer 1600 of FIG. 17 that include trenches of staircase structures 334 in staircase region 1712 of die portion 1611 in FIG. 17, trenches of staircase structures 334′ between block 290 of die portion 1611 and scribe line region 1602 in FIG. 17, trenches of trench structures 344″ in the scribe lines regions (e.g., scribe line region 1602 in FIG. 17) of wafer 1600, trenches of staircase structures 334′ between scribe line region 1602 in FIG. 17 and block 297 of die portion 1611, and trenches of staircase structures 334 in staircase region 1712 of die portion 1612.

For simplicity, only a portion of wafer 1600 of FIG. 16 is shown in FIG. 21A and FIG. 21B. The processes associated with FIG. 21A and FIG. 21B also form photoresists and trenches like photoresist 2115 and trenches 2134T in other die portions and scribe line regions of wafer 1600. Photoresist 2115 is removed from wafer 1600 after trenches 2134T are formed.

Trenches for other staircase structures (e.g., staircase structures 331, 332, and 333 in FIG. 17) and other trench structures in the die portions and the scribe line regions of wafer 1600 can also be formed by similar processes of forming trenches 2134T in FIG. 21A and FIG. 21B.

Forming wafer 1600 in the processes described above with reference to FIG. 21A and FIG. 21B provides improvements and benefits over an alternative process. For example, in an alternative process, photoresist 2115 (FIG. 21A and FIG. 21B) may be formed (e.g., patterned) such that it does not have openings 2134 over the scribe line regions (e.g., scribe line region 1602 in FIG. 21B). In such an alternative process, portions 2115P near blocks 290 and 297 in a particular die portion may tilt toward an adjacent boundary of the particular die portion. For example, without openings 2134 in scribe line region 1602 in FIG. 21A and FIG. 21B in an alternative process, portions 2115P near block 297 in die portion 1611 may tilt toward scribe line region 1602, and portions 2115P near block 290 in die portion 1612 may tilt toward scribe line region 1602. Similar to the tilt in photoresist portions described above in the alternative process associated with FIG. 19A and FIG. 19B, the tilt of photoresist portions 2115P of photoresist 2115 in FIG. 21A and FIG. 21B can cause misalignment in the dielectric structures (e.g., block dividers) and asymmetry in sidewalls of the staircase structures in some of the blocks (e.g., blocks 290 and 297) in the die portions (e.g., die portions 1611 and 1612) of wafer 1600. The misalignment and asymmetry in sidewalls can impact or cause defects in the structures of the die portions of wafer 1600.

As described above with reference to FIG. 21A and FIG. 21B, the repeated pattern of photoresist 2115 is formed continuously over staircase regions of the die portions and over the scribe line regions between the die portions. This can reduce or eliminate the tilt of photoresist portions 2115P near blocks 290 and 297 of a respective die portion. This in turn can reduce or eliminate misalignment and sidewall asymmetry discussed above. Therefore, the structures of the staircase structures (e.g., staircase structures 331, 332, 333, and 334 in FIG. 17) of the die portions of wafer 1600 can be improved in comparison with a similar wafer formed by an alternative process. Yield may also be higher in comparison with that of the alterative processes.

As described above with reference to FIG. 16 through FIG. 18, memory device 1800 may include a separated die portion (e.g., die portion 1612) of wafer 1600. Thus, improvement and benefits in the structure of the memory device is the same as improvement and benefits in the structure of wafer 1600 formed by the processes described above with reference to FIG. 21A and FIG. 21B.

The illustrations of apparatuses (e.g., memory devices 100, 200, 1200, 1400, 1800, 1900, and 2000) and methods (e.g., methods of forming memory devices described herein) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 1200, 1400, 1800, 1900, and 2000) or a system (e.g., an electronic item that can include any of memory devices 100, 200, 1200, 1400, 1800, 1900, and 2000).

Any of the components described above with reference to FIG. 1 through FIG. 21B can be implemented in a number of ways, including simulation via software. Thus, apparatuses (e.g., memory devices 100, 200, 1200, 1400, 1800, 1900, and 2000), or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The memory devices (e.g., memory devices 100, 200, 1800, and 1900) described herein may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 21B include apparatuses and methods of forming the apparatuses. One of the apparatuses includes tiers located one over another; a first staircase structure formed in the tiers; a second staircase structure formed in the tiers adjacent the first staircase structure, respective portions of conductive materials in the tiers forming a part of the first and second staircase structure and a part of respective control gates associated with memory cells; a first trench structure formed in the tiers adjacent the first staircase structure and the second staircase structure, the first trench structure including length in a direction from the first staircase structure to the second staircase structure; and a second trench structure formed in the tiers adjacent the first trench structure, the second trench structure including a length in the direction from the first staircase structure to the second staircase structure. Other embodiments, including additional apparatuses and methods, are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B, and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B, and C” means A only; B only; or C only. Item A can include a single element or multiple elements. Item B can include a single element or multiple elements. Item C can include a single element or multiple elements.

In the detailed description and the claims, the terms “first,” “second,” and “third,” etc. are used merely as labels, and are not intended to impose numerical requirements on their objects.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
tiers located one over another, the tiers including conductive materials separated from one another;
a first staircase structure formed in the tiers, the conductive materials including respective first portions that collectively form a part of the first staircase structure and form part of respective first control gates associated with memory cells of the apparatus;
a second staircase structure formed in the tiers adjacent the first staircase structure, the conductive materials including respective second portions that collectively form a part of the second staircase structure and a part of respective second control gates associated with the memory cells;
a first trench structure formed in the tiers adjacent the first staircase structure and the second staircase structure, the first trench structure including length in a direction from the first staircase structure to the second staircase structure; and
a second trench structure formed in the tiers adjacent the first trench structure, the second trench structure including a length in the direction from the first staircase structure to the second staircase structure.

2. The apparatus of claim 1, wherein each of the first and second trench structures includes length greater than a sum of lengths of the first staircase structure and second staircase structure.

3. The apparatus of claim 1, wherein:
the first staircase structure includes a trench structure formed in the tiers and including a first depth;
the second staircase structure includes a trench structure formed in the tiers and including a second depth, wherein the second depth is greater than the first depth; and
each of the first and second trench structures includes a third depth, and the third depth is greater than the second depth.

4. The apparatus of claim 1, wherein:
the first trench structure is adjacent the first and second staircase structures;
the first trench structure includes a first sidewall and a second sidewall opposite the first sidewall, the second sidewall being between the first sidewall and the first and second trench structures; and
a distance between the first and second sidewalls at a level of a selected tier among the tiers is greater than a distance between the second sidewall and a sidewall of the first staircase structure at the level of the selected tier.

5. The apparatus of claim 1, wherein:
the first trench structure is adjacent the first and second staircase structures;
the first trench structure includes a first sidewall and a second sidewall opposite the first sidewall, the second sidewall being between the first sidewall and the first and second trench structures; and
a distance between the first and second sidewalls at a level of a selected tier among the tiers is less than a distance between the second sidewall and a sidewall of the first staircase structure at the level of the selected tier.

6. The apparatus of claim 1, further comprising at least one additional staircase structure formed in the tiers adjacent the second staircase structure, wherein the conductive materials include respective additional portions that collectively form a part of the at least one additional staircase structure and form part of respective additional control gates associated with the memory cells, wherein:
the first trench structure is also adjacent the least one additional staircase structure.

7. The apparatus of claim 6, wherein each of the first and second trench structures includes length greater than a sum of lengths of the first staircase structure, second staircase structure, and the at least one additional staircase structure.

8. An apparatus comprising:
a die including a first edge and a second edge;
tiers included in the die and located one over another, the tiers including first conductive materials and second conductive material located on levels different from the first conductive materials;
memory cell blocks included in the die and adjacent each other in a first direction from the first edge to the second edge, the memory cell blocks including a memory cell block nearer the first edge than other memory cell blocks;
each of the memory cell blocks including:
a first staircase structure formed in a first portion of the tiers, and first conductive contacts extending through a first dielectric material in the first staircase structure and contacting the first conductive materials at the first staircase structure; and
a second staircase structure formed in a second portion of the tiers, and second conductive contacts extending through a second dielectric material in the second staircase structure and contacting the second conductive materials at the second staircase structure;
a trench structure formed in the tier between the first edge of the die and the memory cell block nearest the first edge, the trench structure adjacent the first staircase structure and the second staircase structure of the memory cell block nearest the first edge; and
a third dielectric material formed in the trench structure.

9. The apparatus of claim 8, further comprising:
an additional trench structure formed in the tier between the second edge of the die and a memory cell block nearer the second edge, the additional trench structure adjacent the first staircase structure and the second staircase structure of the memory cell block nearest the second edge; and
a fourth dielectric material formed in the second trench structure.

10. The apparatus of claim 8, further comprising additional conductive contacts extending through the third dielectric material in a direction parallel to a direction from one tier to another tier among the tiers.

11. The apparatus of claim 8, wherein the memory cell block nearest the first edge is a dummy memory cell block.

12. The apparatus of claim 8, wherein the memory cell block nearest the first edge is a normal memory cell block.

13. The apparatus of claim 8, wherein the trench structure is a first trench structure, and the apparatus further comprises:
a second trench structure in the tiers and adjacent the first trench structure and between the first edge of the die and the first trench structure.

14. An apparatus comprising:
a die including an edge;
a scribe line region adjacent the edge;
a memory cell region including memory cells;
a staircase region adjacent the memory cell region in a first direction;
staircase structures in the staircase region, the staircase structures adjacent each other in a second direction; and
trench structures adjacent the staircase structures in the second direction, wherein a portion of the trench structures is located in the scribe line region.

15. The apparatus of claim 14, wherein the trench structure is a first trench structure, and the apparatus further comprises:
a second trench structure adjacent the first trench structure and between the first edge of the die and the first trench structure.

16. The apparatus of claim 14, wherein the staircase structures and the trench structures are arranged in multiple rows in the staircase region and the scribe line region.

17. The apparatus of claim 16, the rows including a first row and a second row, and wherein:
the staircase structures and the trench structures in the first row have a same length; and
the staircase structures and the trench structures in the second row have a same length.

18. The apparatus of claim 16, wherein the edge of the die is a first edge, the scribe line region is a first scribe line region, and the die further includes:
a second edge opposite the first edge;
a second scribe line region adjacent the second edge; and
additional trench structures adjacent the staircase structures in the second direction between the second edge and the staircase structures, wherein a portion of the additional trench structures is located in the second scribe line region.

19. The apparatus of claim 18, wherein:
a first portion of the staircase structures, a first portion of the trench structures, and a first portion of the additional trench structures form a first row; and
a second portion of the staircase structures, a second portion of the trench structures, and a second portion of the additional trench structures form a second row.

20. An apparatus comprising:
die portions included in a semiconductor wafer, the die portions including a first die portion and a second die portion, each of the first die portion and the second die portion including a memory cell region and a staircase region adjacent the memory cell region in a first direction, the staircase region including staircase structures adjacent each other in a second direction from the first die portion to the second die portion;
scribe line regions between the die portions, the scribe line regions including a scribe line region between the first die portion and the second die portion; and
trench structures formed in the first die portion and the second die portion and in the scribe line region between the first die portion and the second die portion, wherein a portion of the staircase structures of each of the first die portion and the second die portion and a portion of the trench structures are arranged in a row between the staircase region of the first die portion and the staircase region of the second die portion.

21. The apparatus of claim 20, wherein the row is a first row, and an additional portion of the staircase structures of each of the first die portion and the second die portion and an additional portion of the trench structures are arranged in a second row between the staircase region of the first die portion and the staircase region of the second die portion.

22. The apparatus of claim 20, wherein the staircase structures of each of the first die portion and the second die portion in the first row have a different length from the staircase structures of each of the first die portion and the second die portion in the second row.

23. A method comprising:
forming tiers one over another, the tiers including conductive materials separated from one another;
forming a first staircase structure in the tiers, such that the conductive materials include respective first portions that collectively form a part of the first staircase structure and form part of respective first control gates associated with memory cells of a memory device;
forming a second staircase structure in the tiers adjacent the first staircase structure, such that the conductive materials include respective second portions that collectively form a part of the second staircase structure and a part of respective second control gates associated with the memory cells;
forming a first trench structure in the tiers at a side of the first staircase structure and a side of the second staircase structure, such that the first trench structure includes a length in a direction from the first staircase structure to the second staircase structure; and
forming a second trench structure in the tiers adjacent the first trench structure, such that the second trench structure includes a length in the direction from the first staircase structure to the second staircase structure.

24. The method of claim 23, wherein forming the first trench structure and the second trench structure includes:
forming a photoresist over locations of the first staircase structure and the second staircase structure, such that the photoresist includes a first opening having a length corresponding to the length of the first trench structure, and such that the photoresist includes a second opening adjacent the first opening and having a length corresponding the length of the second trench structure.

25. The method of claim 24, wherein the photoresist includes a third opening over a location of one of the staircase structures and adjacent the first opening, wherein the length of each of the first and second opening is greater than a length of the third opening.

26. A method comprising:
forming first staircase structures in a first staircase region in a first die portion of a semiconductor wafer, the first staircase region adjacent a memory cell region of the first die portion in a first direction;
forming second staircase structures in a second staircase region in a second die portion of the semiconductor wafer, the second staircase region adjacent a memory cell region of the second die portion, the second die portion separated from the first die portion by a scribe line region; and
forming trench structures in the first die portion and the second die portion and in the scribe line region, such that a portion of each of the first staircase structures and the second staircase structures and a portion of the trench structures are arranged in a row between the staircase region of the first die portion and the staircase region of the second die portion.

27. The method of claim 26, wherein forming first and second staircase structures and the trench structures includes:
forming a photoresist having first openings over locations of the trench structures in the first die portion, second openings over locations of the trench structures in the second die portion, and third openings over locations of the trench structures in the scribe line region.

28. The method of claim 27, wherein the photoresist includes portions between the first, second, and third openings, wherein the portions have a same width.

29. The method of claim 26, wherein the first, second, and third openings include a same length.

30. The method of claim 26, wherein the first, second, and third openings include a same width.
